(19) United States
(12) Patent Application Publication
(10) Pub. No.: US 2022/0336586 A1
(43) Pub. Date: Oct. 20, 2022

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Ji Young KIM, Hwaseong-si (KR); Dong-Sik LEE, Hwaseong-si (KR); Joon-Sung LIM, Seongnam-si (KR); Bum Kyu KANG, Suwon-si (KR); Ho Jun SEONG, Suwon-si (KR)

(21) Appl. No.: 17/504,312

(22) Filed: Oct. 18, 2021

(30) Foreign Application Priority Data
Apr. 19, 2021 (KR) 10-2021-0050543

(51) Int. Cl. H01L 29/10; H01L 27/11582

(52) U.S. Cl. CPC H01L 29/1037; H01L 27/11582

(57) ABSTRACT

A semiconductor device includes a substrate, a first stack structure on the substrate and includes a plurality of first gate electrodes, a second stack structure on the first stack structure and includes a plurality of second gate electrodes, a channel hole including a first lower channel hole that extends through a lower portion of the first stack structure, a first upper channel hole connected to the first lower channel hole, and a second channel hole connected to the first upper channel hole, and a channel structure in the channel hole. A side wall of the first lower channel hole has a first inclination relative to the first direction, a side wall of the first upper channel hole has a second inclination relative to the first direction, and a side wall of the second channel hole has a third inclination relative to the first direction.

### CROSS-REFERENCE TO RELATED APPLICATION

This application claims priority from Korean Patent Application No. 10-2021-0050543 filed on Apr. 19, 2021 in the Korean Intellectual Property Office, and all the benefits accruing therefrom under 35 U.S.C. 119, the contents of which in its entirety are herein incorporated by reference.

### BACKGROUND

The present disclosure relates to a semiconductor device and an electronic system including the same.

There is a demand for a semiconductor device capable of storing high-capacity data in electronic systems that include data storage. Accordingly, schemes for increasing data storage capacity of the semiconductor device is being studied. For example, one of the schemes for increasing the data storage capacity of the semiconductor device is to employ a semiconductor device including three-dimensional memory cells instead of two-dimensional memory cells.

### SUMMARY

A semiconductor device includes a substrate, a first stack structure on the substrate, the first stack structure includes a plurality of first gate electrodes stacked in a first direction, a second stack structure on the first stack structure, the second stack structure includes a plurality of second gate electrodes stacked in the first direction, a channel hole that includes a first lower channel hole that extends through a lower portion of the first stack structure, a first upper channel hole connected to the first lower channel hole and extends through an upper portion of the first stack structure, and a second channel hole connected to the first upper channel hole and extends through the second stack structure, and a channel structure in the channel hole. A side wall of the first lower channel hole has a first inclination relative to the first direction, a side wall of the first upper channel hole has a second inclination relative to the first direction, the second inclination is different from the first inclination, a side wall of the second channel hole has a third inclination relative to the first direction, and the third inclination is different from the second inclination.

A semiconductor device includes a substrate, a first stack structure on the substrate and including a plurality of first inter-electrode insulating films and a plurality of first gate electrodes alternately stacked in a first direction, a second stack structure on the first stack structure, and including a plurality of second inter-electrode insulating films and a plurality of second gate electrodes alternately stacked in the first direction, a channel hole including a first lower channel hole that extends through a lower portion of the first stack structure, a first upper channel hole that is connected to the first lower channel hole and extends through an upper portion of the first stack structure, and a second channel hole that is connected to the first upper channel hole and extends through the second stack structure, a channel structure including a channel insulating film on a surface of the channel hole, a channel film on the channel insulating film, and a channel filling film on the channel film and in the channel hole, a source conductive layer between the substrate and the first stack structure, and a support layer between the source conductive layer and the first stack structure. The support layer extends through the channel insulating film and directly contacts the channel film. A side wall of the first lower channel hole has a first inclination relative to the first direction. A side wall of the first upper channel hole has a second inclination relative to the first direction. The second inclination is different from the first inclination. A side wall of the second channel hole has a third inclination relative to the first direction. The third inclination is different from the second inclination.

An electronic system includes a main substrate, a semiconductor device on the main substrate, and a controller on the main substrate and electrically connected to the semiconductor device. The semiconductor device includes a first structure including a peripheral circuit, a second structure including an input/output connection wire electrically connected to the peripheral circuit, and an input/output pad electrically connected to the input/output connection wire which extends into the second structure. The second structure includes a first stack structure on a substrate, such that the first stack structure includes a plurality of first gate electrodes stacked in a first direction, a second stack structure on the first stack structure, such that the second stack structure includes a plurality of second gate electrodes stacked in the first direction, a channel hole including a first lower channel hole that extends through a lower portion of the first stack structure, a first upper channel hole connected to the first lower channel hole and extends through an upper portion of the first stack structure, and a second channel hole connected to the first upper channel hole and extends through the second stack structure, and a channel structure in the channel hole. A side wall of the first lower channel hole has a first inclination relative to the first direction. A side wall of the first upper channel hole has a second inclination relative to the first direction. The second inclination is different from the first inclination, and a side wall of the second channel hole has a third inclination relative to the first direction. The third inclination is different from the second inclination.

A technical purpose to be achieved by the present disclosure is to provide a semiconductor device having improved device reliability.

Another technical purpose to be achieved by the present disclosure is to provide an electronic system including a semiconductor device having improved device reliability.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using embodiments shown in the claims and combinations thereof.

### BRIEF DESCRIPTION OF DRAWINGS

The above and other aspects and features of the present disclosure will become more apparent by describing in detail example embodiments thereof with reference to the attached drawings, in which:

FIG. 1 is a diagram for illustration of a wafer on which a semiconductor device is formed according to some embodiments;

FIG. 2 is an enlarged schematic layout diagram of a portion of a chip area of FIG. 1;

FIG. 3 is a cross-sectional view taken along a line A-A of FIG. 2;

FIG. 4 is an enlarged view of a R1 area in FIG. 3;

FIG. 5 is a cross-sectional view taken along a line B-B in FIG. 1;

FIG. 6 to FIG. 14 are diagrams for illustration of a semiconductor device according to some embodiments;

FIG. 15 to FIG. 27 are diagrams of intermediate structures to illustrate a method for manufacturing a semiconductor device according to some embodiments;

FIG. 28 and FIG. 29 are diagrams of intermediate structures to illustrate a method for manufacturing a semiconductor device according to some embodiments;

FIG. 30 to FIG. 33 are diagrams of intermediate structures to illustrate a method for manufacturing a semiconductor device according to some embodiments;

FIG. 34 to FIG. 41 are diagrams of intermediate structures to illustrate a method for manufacturing a semiconductor device according to some embodiments;

FIG. 42 and FIG. 43 are diagrams of intermediate structures to illustrate a method for manufacturing a semiconductor device according to some embodiments;

FIG. 44 is a schematic diagram of an electronic system including a semiconductor device according to some embodiments;

FIG. 45 is a schematic perspective view of an electronic system including a semiconductor device according to some embodiments; and

FIG. 46 and FIG. 47 are schematic cross-sectional views of semiconductor packages according to some embodiments.

### DETAILED DESCRIPTIONS

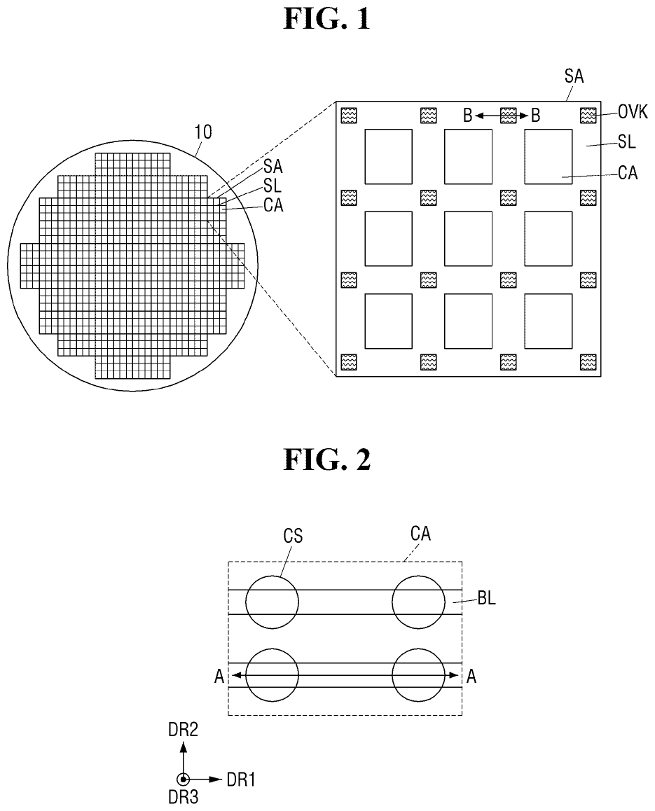

FIG. 1 is a diagram for illustration of a wafer on which a semiconductor device is formed according to some embodiments.

Referring to FIG. 1, a semiconductor device according to some embodiments may be formed on a wafer 10. The wafer 10 may include a plurality of shot areas SA. The shot area SA may be an area exposed in a single exposure process. The shot area SA may include at least one chip areas CA. A scribe lane area SL may be disposed between the chip areas CA. After forming a semiconductor element on a semiconductor chip, a dicing process divides a semiconductor wafer into semiconductor chips. The scribe lane area SL may refer to an area used for the dicing process. The chip area CA may be defined by the scribe lane area SL.

An overlay key OVK used in exposure processes performed to form a semiconductor element may be disposed in the scribe lane area SL. A layout of the overlay key OVK is not limited to what is shown in this drawing. The overlay key OVK may be disposed in various layouts and at various locations within the scribe lane area SL. Various keys such as an alignment key, a focus key, etc. in addition to the overlay key OVK may be disposed in the scribe lane area SL.

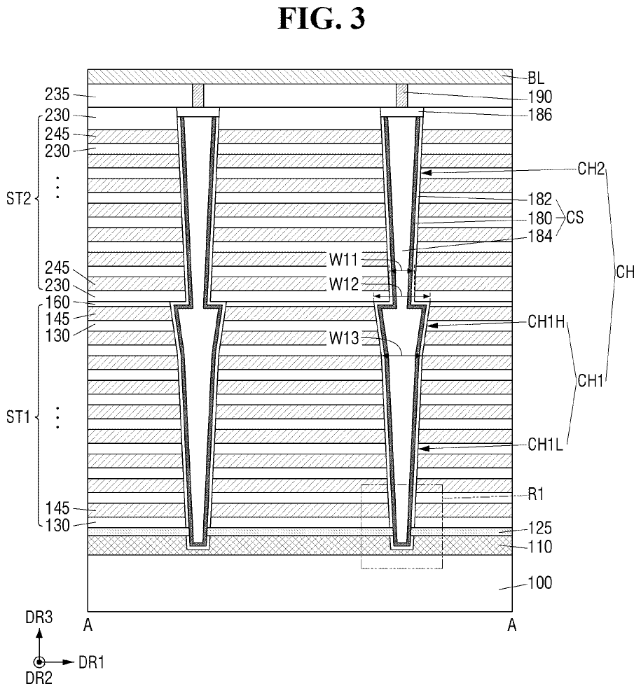

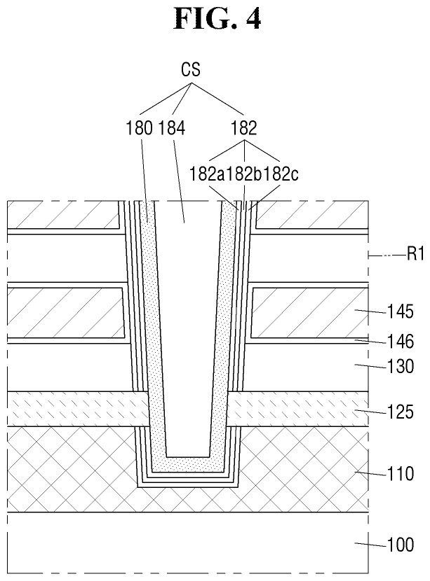

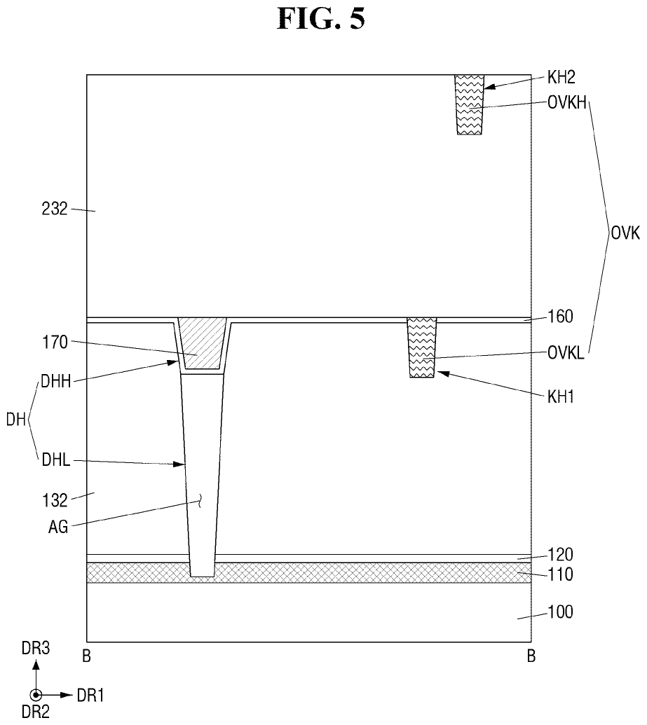

FIG. 2 is an enlarged schematic layout diagram of a portion of the chip area of FIG. 1. FIG. 3 is a cross-sectional view taken along a line A-A of FIG. 2. FIG. 4 is an enlarged view of a R1 area in FIG. 3. FIG. 5 is a cross-sectional view taken along a line B-B in FIG. 1.

Referring to FIG. 1 to FIG. 5, a semiconductor device according to some embodiments disposed in the chip area CA may include a substrate 100, a source conductive layer 110, a support layer 125, a first stack structure ST1, a second stack structure ST2, an upper insulating film 235, and a bit line BL. The semiconductor device according to some embodiments disposed in the scribe lane area SL may include the substrate 100, the source conductive layer 110, a support layer 125, a first filling oxide film 132, a first interlayer insulating film 160, a second filling oxide film 232 and an overlay key OVK.

The substrate 100 may include at least one of a silicon substrate, a silicon germanium substrate, a germanium substrate, SGOI (silicon germanium on insulator), SOI (silicon-on-insulator), or GOI (germanium-on-insulator). In some embodiments, the substrate 100 may include a semiconductor material such as indium antimonide, lead tellurium compound, indium arsenic, indium phosphide, gallium arsenide or gallium antimonide. However, the present disclosure is not limited thereto.

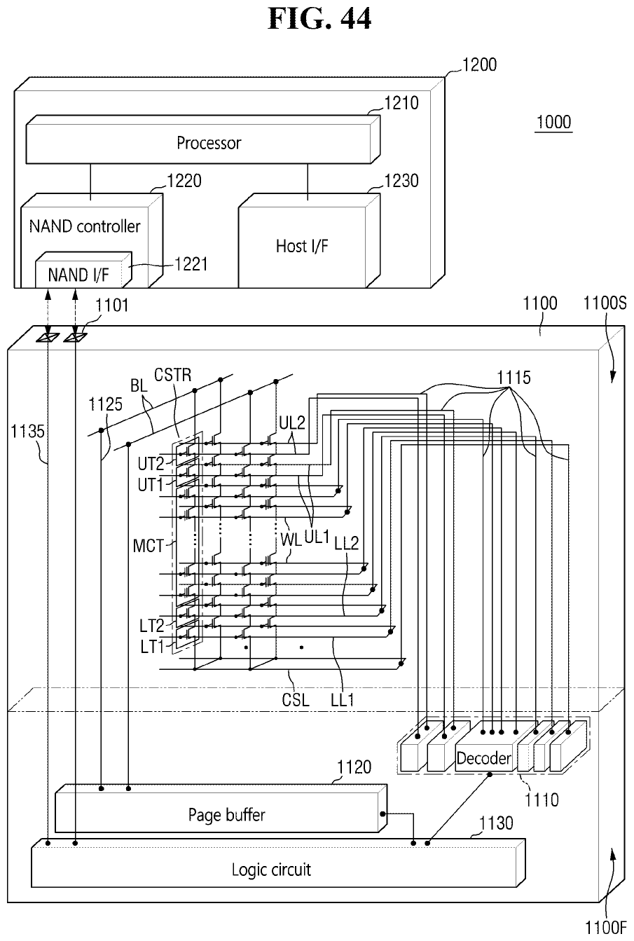

The source conductive layer 110 may be disposed on the substrate 100. The source conductive layer 110 may be embodied as a common source plate. The source conductive layer 110 may act as a common source line (CSL in FIG. 44).

The source conductive layer 110 may include at least one of a conductive semiconductor film, a metal silicide film, or a metal film. When the source conductive layer 110 includes the conductive semiconductor film, the source conductive layer 110 may include at least one of, for example, silicon (Si), germanium (Ge), silicon germanium (SiGe), gallium arsenide (GaAs), indium gallium arsenide (InGaAs), aluminum gallium arsenide (AlGaAs), or combinations thereof. The source conductive layer 110 may have at least one selected from single crystal, amorphous and polycrystalline structures. The source conductive layer 110 may include at least one of p-type impurities, n-type impurities, or carbon included in the semiconductor film.

The support layer 125 may be disposed on the source conductive layer 110. The support layer 125 may include, for example, a semiconductor material such as silicon (Si), germanium (Ge) or a mixture thereof.

The first stack structure ST1 may be disposed on the support layer 125. The first stack structure ST1 may include a plurality of first inter-electrode insulating films 130 and a plurality of first gate electrodes 145 alternately stacked one on top of another in a third direction DR3, and a first interlayer insulating film 160. The first inter-electrode insulating film 130 may be disposed between adjacent two first gate electrodes 145 spaced from each other in the third direction DR3. Each of the first inter-electrode insulating film 130 and the first gate electrode 145 may have a layered structure extending in a first direction DR1 and a second direction DR2.

The second stack structure ST2 may be disposed on the first stack structure ST1. The second stack structure ST2 may be disposed on the first interlayer insulating film 160. The second stack structure ST2 may include a plurality of second inter-electrode insulating films 230 and a plurality of second gate electrodes 245 alternately stacked one on top of another in the third direction DR3. The second inter-electrode insulating film 230 may be disposed between adjacent two second gate electrodes 245 spaced from each other in the third direction DR3. Each of the second inter-electrode insulating film 230 and the second gate electrode 245 may have a layered structure extending in the first direction DR1 and the second direction DR2.

Each of the first gate electrode 145 and the second gate electrode 245 may include, for example, a conductive material. For example, the first gate electrode 145 may include a metal such as tungsten (W), cobalt (Co), nickel (Ni), or a semiconductor material such as silicon. However, the present disclosure is not limited thereto.

Each of the first inter-electrode insulating film 130 and the second inter-electrode insulating film 230 may include an insulating material. For example, the first inter-electrode insulating film 130 may include silicon oxide. However, the present disclosure is not limited thereto.

The first interlayer insulating film 160 may act as a topmost film of the first stack structure ST1 in the third direction DR3. For example, the first interlayer insulating film 160 may be disposed on a top face of the topmost first gate electrode 145 in the third direction DR3. In some embodiments, a thickness of the first interlayer insulating film 160 in the third direction DR3 may be 10 nm or smaller. In some embodiments, the first interlayer insulating film 160 may include an oxide film ALD-OX formed by an atomic layer deposition process at room temperature. However, the present disclosure is not limited thereto.

A channel hole CH may extend in the third direction DR3. The channel hole CH may include a first channel hole CH1 extending through the first stack structure ST1 and a second channel hole CH2 extending through the second stack structure ST2.

The first channel hole CH1 may include a first lower channel hole CH1L extending through a lower portion of the first stack structure ST1 and thus extending through some of the first gate electrodes 145, and a first upper channel hole CH1H extending through an upper portion of the first stack structure ST1 and thus extending through the other of the first gate electrodes 145. The first upper channel hole CH1H may extend through the first interlayer insulating film 160. The second channel hole CH2 may extend through the second gate electrodes 245. The first upper channel hole CH1H may be connected to the first lower channel hole CH1L, and the second channel hole CH2 may be connected to the first upper channel hole CH1H.

A side wall of the first channel hole CH may have an inclination change at a boundary between the first lower channel hole CH1L and the first upper channel hole CH1H. A side wall of the first lower channel hole CH1L may a have first inclination relative to the third direction DR3. A side wall of the first upper channel hole CH1H may have a second inclination different from the first inclination relative to the third direction DR3. The second inclination may be greater than the first inclination in some embodiments. A side wall of the second channel hole CH2 may have a third inclination relative to the third direction DR3. The second inclination may be greater than the third inclination in some embodiments. However, the present disclosure is not limited thereto.

A width in the first direction DR1 of the channel hole CH may increase as the channel hole extends in a direction away from a top face of the substrate 100. Hereinafter, the “width” will be described relative to the first direction DR1. A width of the first lower channel hole CH1L may increase up to W13 as it extends in a direction away from the top face of the substrate 100. A width of the first upper channel hole CH1H may increase from W13 to W12 as it extends in a direction away from the top face of the substrate 100. A width of the second channel hole CH2 may increase from W11 as it extends in a direction away from the top face of the substrate 100. At a boundary between the first upper channel hole CH1L and the second channel hole CH2, the width W12 of the first upper channel hole CH1L may be larger than the width W11 of the second channel hole CH2.

A channel structure CS may be disposed in the channel hole CH. Accordingly, the channel structure CS may include a first portion whose width increases to W13 as it extends in a direction away from the top face of the substrate 100, a second portion whose width increases from W13 to W12 as it extends in a direction away from the top face of the substrate 100, and a third portion whose width increases from W11 as it extends in a direction away from the top face of the substrate 100. At a boundary between the second portion and the third portion, a width may be reduced from W12 to W11.

The channel structure CS may extend through the first stack structure ST1 and the second stack structure ST2. The channel structure CS may extend in the third direction DR3. The channel structure CS may include a channel insulating film 182 continuously formed along a profile of the channel hole CH, a channel film 180 on the channel insulating film 182, and a channel filling film 184 disposed on the channel film 180 and filling or at least partially filling the channel hole CH.

The channel film 180 may extend through the first stack structure ST1 and the second stack structure ST2 and thus may intersect with the plurality of first gate electrodes 145 and the plurality of second gate electrodes 245. The channel film 180 is shown to have a cup shape with portions on the sidewalls of the channel hole CH and the bottom of the channel hole CH. However, this is only an example. For example, the channel film 180 may have various shapes such as a hollow cylindrical shape, a hollow box shape, and/or a filled filler shape.

The channel film 180 may include, for example, a semiconductor material such as single crystal silicon, polycrystalline silicon, an organic semiconductor material, and/or a carbon nano structure. However, the present disclosure is not limited thereto.

The channel insulating film 182 may be interposed between the channel film 180 and the first and second gate electrodes 145 and 245. The channel insulating film 182 may extend along a side face of the channel film 180.

The channel insulating film 182 may include, for example, at least one of silicon oxide, silicon nitride, silicon oxynitride, or a high-k material having a higher dielectric constant than that of silicon oxide. The high-k material may include, for example, aluminum oxide, hafnium oxide, lanthanum oxide, tantalum oxide, titanium oxide, lanthanum hafnium oxide, lanthanum aluminum oxide, dysprosium scandium oxide, or combinations thereof.

In some embodiments, the channel insulating film 182 may include a plurality of films. For example, the channel insulating film 182 may include a tunnel insulating film 182a, a charge storage film 182b, and a blocking insulating film 182c which are sequentially stacked on the channel film 180.

The tunnel insulating film 182a may include, for example, silicon oxide or a high dielectric constant material having a higher dielectric constant than that of silicon oxide. The high dielectric constant material may include, for example, aluminum oxide (Al₂O₃), and/or hafnium oxide (HfO₂). The charge storage film 182b may include, for example, silicon nitride. The blocking insulating film 182c may include, for example, silicon oxide or a high dielectric constant material having a higher dielectric constant than that of silicon oxide. The high dielectric constant material may include, for example, aluminum oxide (Al₂O₃), and/or hafnium oxide (HfO₂).

Each of the tunnel insulating film 182a, the charge storage film 182b, and the blocking insulating film 182c may be discontinuous in a lower portion of the channel structure CS. The support layer 125 may fill the discontinue space of one or more of the tunnel insulating film 182a, the charge storage film 182b, and/or the blocking insulating film 182c. The support layer 125 may electrically connect the source conductive layer 110 and the channel film 180 to each other.

The channel filling film 184 may be formed to fill an inside of the channel film 180. The channel film 180 may extend along a side face and a bottom face of the channel filling film 184. The channel filling film 184 may include, for example, silicon oxide. However, the present disclosure is not limited thereto.

An insulation pattern 146 may be disposed between each of the first and second gate electrodes 145 and 245 and the channel insulating film 182. The insulating pattern 146 may include, for example, silicon oxide or a high-k material such as aluminum oxide (Al₂O₃) and/or hafnium oxide (HfO₂).

Unlike shown, the insulating pattern 146 may not be disposed between each of the first and second gate electrodes 145 and 245 and the channel insulating film 182.

A bit line pad 186 may be disposed on a top face of the channel structure CS. The bit line pad 186 may be disposed in the topmost second inter-electrode insulating film 230 of the second stack structure ST2 in the third direction DR3. The bit line pad 186 may include a conductive material. For example, the bit line pad 186 may include a semiconductor material doped with n-type impurities.

An upper insulating film 235 may be disposed on a top face of the second stack structure ST2. The upper insulating film 235 may include, for example, at least one of silicon oxide, silicon oxynitride, or a low dielectric constant material, but is not limited thereto.

The bit line BL may be disposed on a top face of the upper insulating film 235. The bit line BL may extend in an elongated manner in the first direction DR1. The bit line BL may be electrically connected to the channel structure CS by a bit line plug 190 extending through the upper insulating film 235. Each of the bit line BL and the bit line plug 190 may include, for example, a conductive material.

In one example, referring to FIG. 5, a first filling oxide film 132 may be disposed on the support layer 125. A dummy hole DH may extend in the third direction DR3. The dummy hole DH may include a lower dummy hole DHL extending through a lower portion of the first filling oxide film 132, and an upper dummy hole DHH extending through an upper portion of the first filling oxide film 132 and connected to the lower dummy hole DHL.

A side wall of the dummy hole DH may have an inclination change at a boundary between the lower dummy hole DHL and the upper dummy hole DHH. Specifically, a side wall of the lower dummy hole DHL may have a fourth inclination relative to the third direction DR3. A side wall of the upper dummy hole DHH may have a fifth inclination different from the fourth inclination relative to the third direction DR3. The fifth inclination may be greater than the fourth inclination in one example. A width in the first direction DR1 of the dummy hole DH may increase as it extends in a direction away from the top face of the substrate 100. That is, a width in the first direction DR1 of the dummy hole DH may increase as it extends in the third direction DR3.

The first interlayer insulating film 160 may extend along a top face of the first filling oxide film 132 and the side wall of the upper dummy hole DH. The first interlayer insulating film 160 may define an air gap AG in the lower dummy hole DHL. That is, the air gap AG may be defined by the lower dummy hole DHL and the first interlayer insulating film 160.

An etching stopper film 170 may be disposed on the first filling oxide film 132 to fill or at least partially fill the upper dummy hole DHH. In some embodiments, the etching stopper film 170 may be made of a material having an etching selectivity to oxides and/or nitrides. The etching stopper film 170 may include, for example, polysilicon, AlO, and the like. However, the present disclosure is not limited thereto. In some embodiments, the etching stopper film 170 may include, for example, a metal material. The etching stopper film 170 may include, for example, TiN, W, and the like. However, the present disclosure is not limited thereto.

A first keyhole KH1 may extend through the first interlayer insulating film 160 and an upper portion of the first filling oxide film 132. A first overlay key OVKL may be disposed in the first keyhole KH1.

A second filling oxide film 232 may be disposed on the first interlayer insulating film 160. Each of the first filling oxide film 132 and the second filling oxide film 232 may include an oxide-based material such as silicon oxide (Sift), silicon oxycarbide (SiOC), or silicon oxyfluoride (SiOF).

A second keyhole KH2 may extend through the upper portion of the second filling oxide film 232. A second overlay key OVKH may be disposed in the second keyhole KH2. The second overlay key OVKH may not overlap with the first overlay key OVKL in the third direction DR3. Using the overlay key OVK, which includes the first overlay key OVKL and the second overlay key OVKH, the second stack structure ST2 may be aligned, in the third direction DR3, with the first stack structure ST1.

An arrangement and/or a shape of the first keyhole KH1 and the second keyhole KH2 may vary as not shown in FIG. 5.

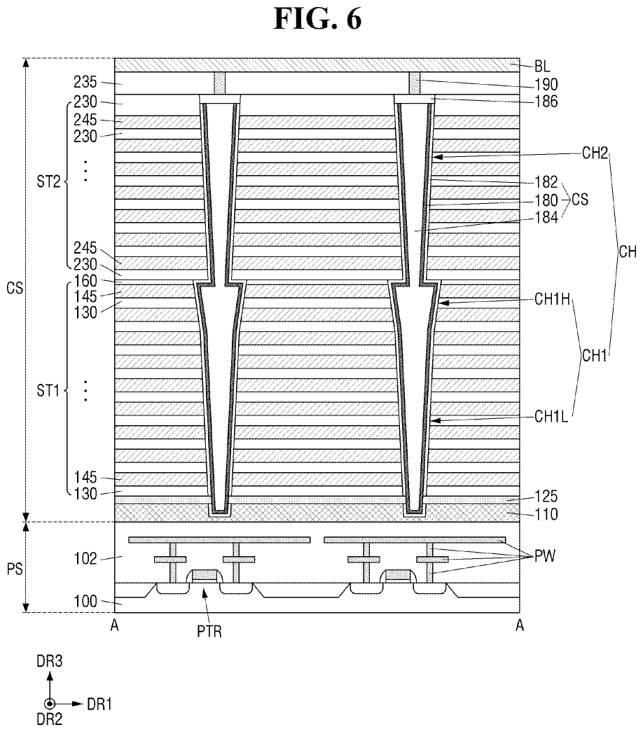

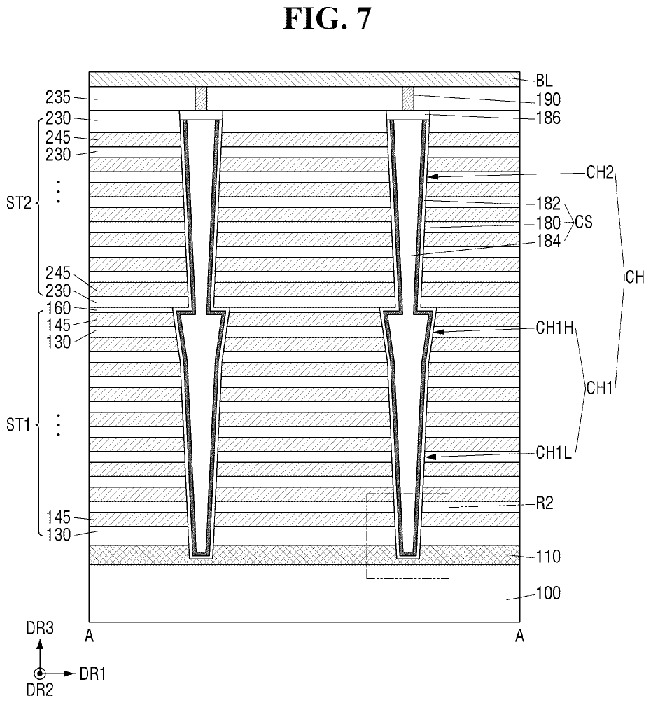

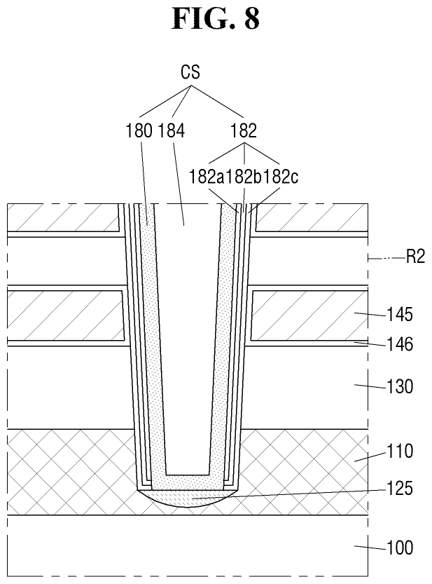

FIG. 6 to FIG. 14 are diagrams for illustration of a semiconductor device according to some embodiments. FIG. 6, FIG. 7 and FIG. 9 to FIG. 14 may be a cross-sectional view taken along a line A-A in FIG. 2. FIG. 8 is an enlarged view of a R2 area in FIG. 7. For convenience of description, following descriptions are based on differences from those described above with reference to FIGS. 1 to 5.

Referring to FIG. 6, a semiconductor device according to some embodiments may include a peripheral circuit structure PS and a cell array structure CS.

The peripheral circuit structure PS may include a peripheral circuit element PTR, a lower connection wire PW, and a peripheral logic insulating film 102.

The peripheral circuit element PTR may be formed on the substrate 100. The peripheral circuit element PTR may include circuits that operate the cell array structure CS.

The peripheral logic insulating film 102 may be formed on the substrate 100. The peripheral logic insulating film 102 may include, for example, at least one of silicon oxide, silicon nitride, silicon oxynitride, or a low dielectric constant material.

The lower connection wire PW may be formed in the peripheral logic insulating film 102. The lower connection wire PW may be connected to the peripheral circuit element PTR.

The cell array structure CS may be disposed on the peripheral logic structure PS. The cell array structure CS may include the substrate 100, the source conductive layer 110, the support layer 125, the first stack structure ST1, the second stack structure ST2, the upper insulating film 235, and the bit line BL. The source conductive layer 110 may extend along a top face of the peripheral logic structure PS.

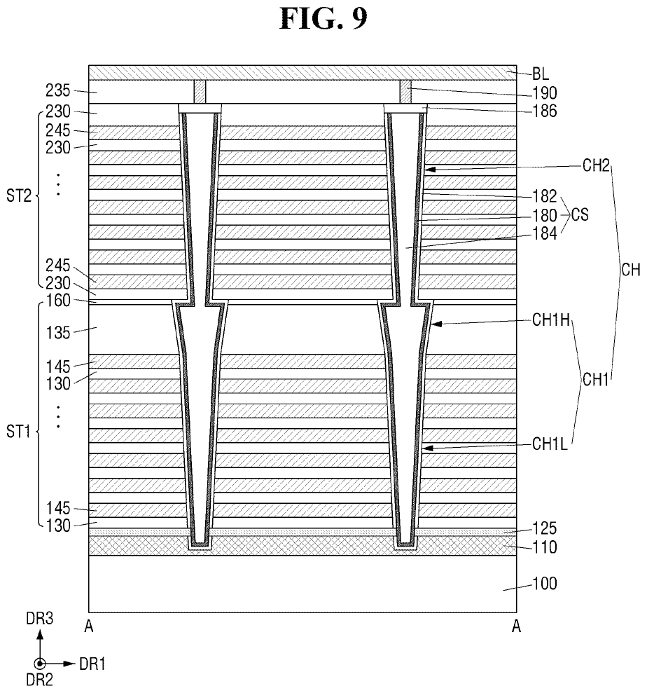

Referring to FIGS. 8 and 9, in a semiconductor device according to some embodiments, the support layer 125 may not be disposed between the source conductive layer 110 and the first stack structure ST1. At least a portion of the source conductive layer 110 may be embedded in the substrate 100. In one example, the source conductive layer 110 may be grown from the substrate 100 using a SEG (selective epitaxial growth) process.

A side wall of the channel film 180 may not be exposed, while a bottom of the channel film 180 may be exposed. A portion of each of the tunnel insulating film 182a, the charge storage film 182b, and the blocking insulating film 182c between the bottom of the channel film 180 and the source conductive layer 110 may be removed. According to some embodiments, the support layer 125 may be on a bottom surface of the channel film 180. The channel film 180 may be electrically connected to the source conductive layer 110 by the bottom of the channel film 180. In some embodiments the channel film 180 may be in direct contact with the source conductive layer 110.

Referring to FIG. 9, in a semiconductor device according to some embodiments, the first interlayer insulating film 160 may be disposed on the topmost first inter-electrode insulating film 135 of the first stack structure ST1. In this connection, a thickness of the topmost first inter-electrode insulating film 135 of the first stack structure ST1 in the third direction DR3 may be larger than each of a thickness of each of other first inter-electrode insulating films 130 in the third direction DR3 and a thickness of the second inter-electrode insulating film 230 in the third direction DR3.

The first lower channel hole CH1L may extend through the first gate electrodes 145. The first upper channel hole CH1H may extend through the first inter-electrode insulating film 135 and the first interlayer insulating film 160, and may not extend through the first gate electrode 145.

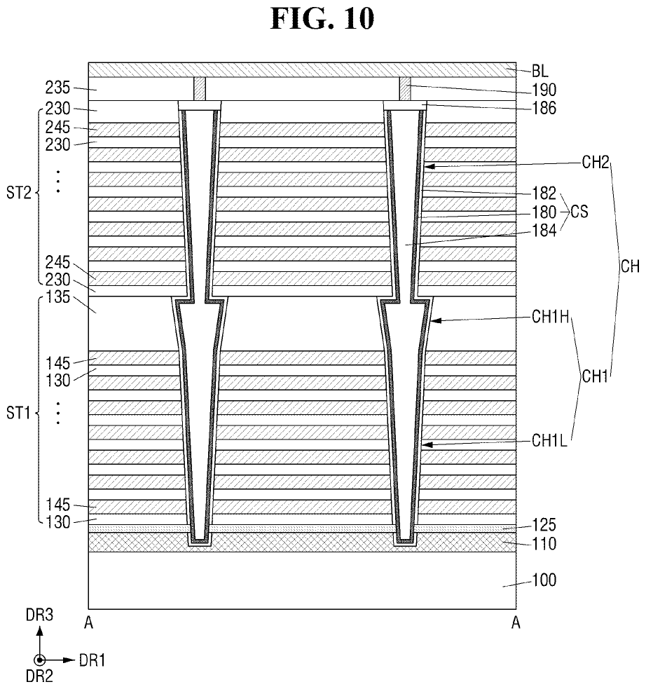

Referring to FIG. 10, unlike FIG. 9, in a semiconductor device according to some embodiments, the first stack structure ST1 may not include the first interlayer insulating film 160. The first upper channel hole CH1H may extend through the first inter-electrode insulating film 135, and may not extend through the first gate electrode 145.

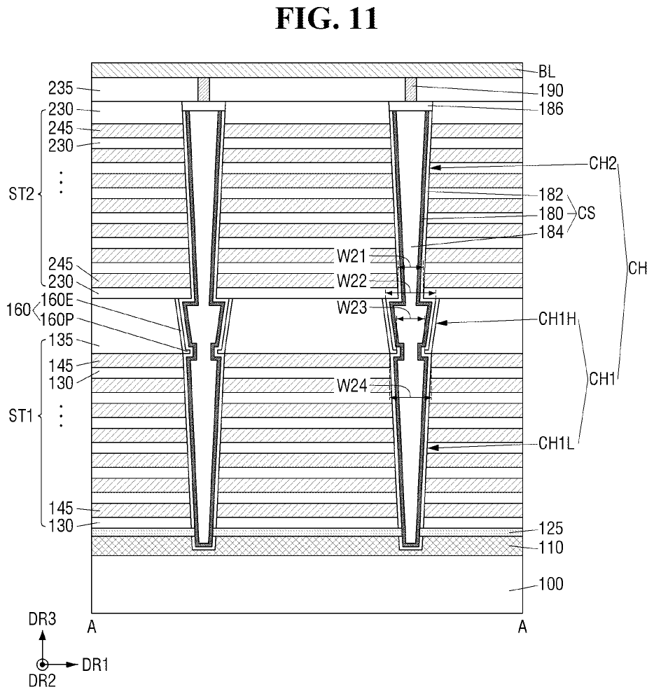

Referring to FIG. 11, unlike FIG. 10, a semiconductor device according to some embodiments may further include a first interlayer insulating film 160 disposed in the first upper channel hole CH1H. The first interlayer insulating film 160 may include an extension 160E extending along a side wall of the first upper channel hole CH1H and a protrusion 160P protruding from the extension 160E.

The extension 160E may be conformally formed along the side wall of the first upper channel hole CH1H.

The protrusion 160P may protrude from a lower portion of the extension 160E toward the channel structure CS. The protrusion 160P may protrude toward the channel structure CS and at a boundary between the first upper channel hole CH1H and the first lower channel hole CH1L. The protrusion 160P may extend along at least a portion of a top face of the topmost first gate electrode 145 of the first stack structure ST1. That is, a bottom face of the protrusion 160P may be substantially coplanar with a top face of the topmost first gate electrode 145 of the first stack structure ST1. Opposite protrusions 160P may be spaced from each other while not being connected to each other.

The channel insulating film 182 may continuously extend along a profile of the second channel hole CH2, a profile of the first interlayer insulating film 160, and a profile of the first lower channel hole CH1L. The channel film 180 may be disposed on the channel insulating film 182. The channel filling film 184 may be disposed on the channel film 180 to fill or at least partially fill the channel hole CH. Accordingly, the channel structure CS may include a first portion whose width increases to W24 as it extends in a direction away from the top face of the substrate 100, a second portion whose width is constant and is W23 smaller than W24, a third portion whose width increases from W23 to W22 as it extends in a direction away from the top face of the substrate 100, and a fourth portion whose width increases from W21 as it extends in a direction away from the top face of the substrate 100. At a boundary between the first portion and the second portion, the width may be reduced from W24 to W23. At a boundary between the second portion and the third portion, the width may be increased from W23 to W22. At a boundary between the third portion and the fourth portion, the width may be reduced from W22 to W21.

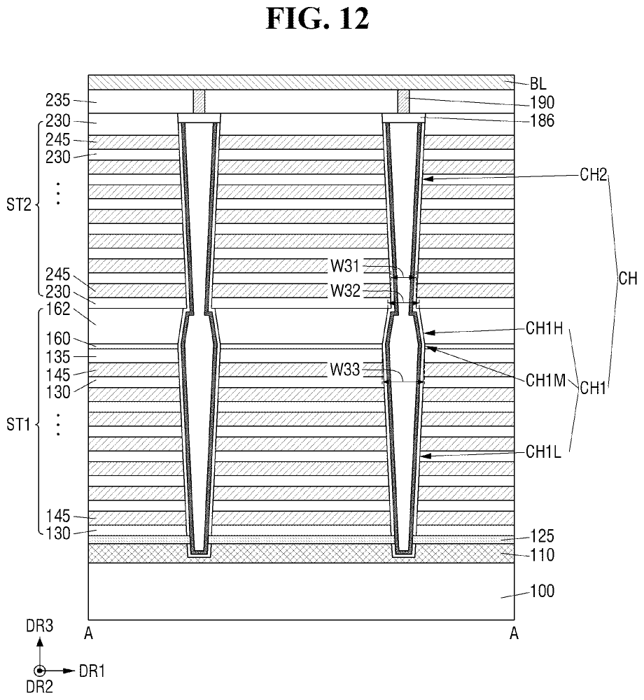

Referring to FIG. 12, unlike FIG. 9, a semiconductor device according to some embodiments may further include a second interlayer insulating film 162. The second interlayer insulating film 162 may be disposed on the first interlayer insulating film 161. A thickness of the second interlayer insulating film 162 in the third direction DR3 may be larger than each of a thickness of the first interlayer insulating film 160, a thickness of each of the first inter-electrode insulating films 130 and 135, and a thickness of the second inter-electrode insulating film 230.

The second interlayer insulating film 162 may include, for example, plasma enhanced TEOS (Tetra Ethyl Ortho Silicate).

The first channel hole CH1 may further include a first middle channel hole CH1M disposed between and connected to the first lower channel hole CH1L and the first upper channel hole CH1L.

The first lower channel hole CH1L may extend through the first gate electrode 145.

The first middle channel hole CH1M may extend through the first interlayer insulating film 160. A side wall of the first middle channel hole CH1M may be defined by the first interlayer insulating film 160. The first interlayer insulating film 160 may be discontinuous in the first direction DR1 while the channel structure CS in the first middle channel hole CH1M fills the discontinuous space.

The first middle channel hole CH1M may have an inclination relative to the third direction DR3 different from inclinations of each of the first lower channel hole CH1L and the first upper channel hole CH1L. For example, a side wall of the first middle channel hole CH1M may be substantially perpendicular to the top face of the substrate 100. That is, a width of the first middle channel hole CH1M may be substantially constant in one example.

The first upper channel hole CH1H may extend through the second interlayer insulating film 162.

A width of the first lower channel hole CH1L may increase up to W33 as it extends in a direction away from the top face of the substrate 100. A width of the second middle channel hole CH1M may be constant, such as W33. A width of the first upper channel hole CH1H may decrease from W33 to W32 as it extends in a direction away from the top face of the substrate 100. A width of the second channel hole CH2 may increase from W31 as it extends in a direction away from the top face of the substrate 100. At a boundary between the first upper channel hole CH1L and the second channel hole CH2, the width W32 of the first upper channel hole CH1L may be larger than the width W31 of the second channel hole CH2.

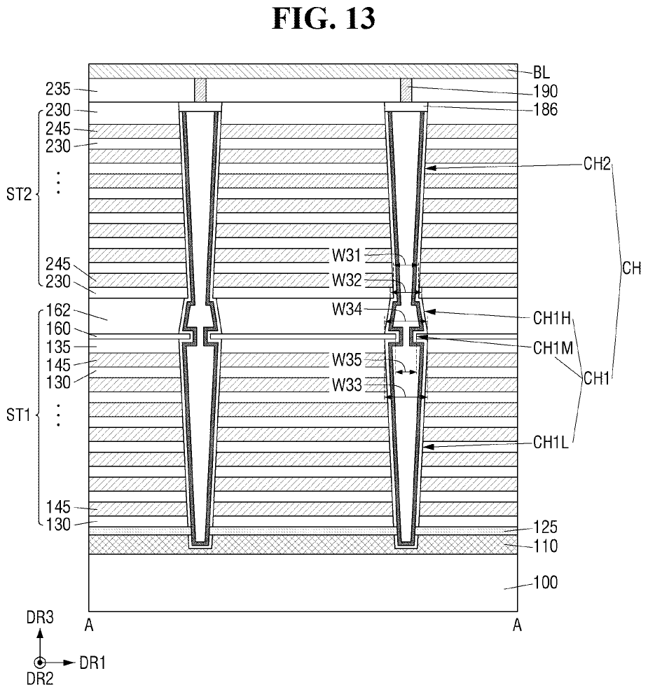

Referring to FIG. 13, unlike FIG. 12, in a semiconductor device according to some embodiments, at a boundary between the first lower channel hole CH1L and the first middle channel hole CH1M, a width W33 of the first lower channel hole CH1L may be larger a width W35 of the first middle channel hole CH1M. At a boundary between the first middle channel hole CH1M and the first upper channel hole CH1H, the width W35 of the first middle channel hole CH1M may be smaller than a width W34 of the first upper channel hole CH1H. A width of the first upper channel hole CH1H may decrease from W34 to W32 as it extends in a direction away from the top face of the substrate 100.

The channel insulating film 182 may extend along a profile of the channel hole CH. The channel insulating film 182 may continuously extend along a profile of a protruding portion 160P2 of the first interlayer insulating film 160. Accordingly, the channel structure CS may include a first portion whose width increases to W33 as it extends in a direction away from the top face of the substrate 100, a second portion whose width is constant and W35 smaller than W33, a third portion whose width decreases from W34 larger than W35 to W32 as it extends in a direction away from the top face of the substrate 100, and a fourth portion whose width increases from W31, which is smaller than W32, as it extends in a direction away from the top face of the substrate 100. At a boundary between the first portion and the second portion, the width may be reduced from W33 to W35. At a boundary between the second portion and the third portion, the width may be increased from W35 to W34. At a boundary between the third portion and the fourth portion, the width may be reduced from W32 to W31. The first portion and the third portion may be spaced apart from each other in the third direction DR3 by the first interlayer insulating film 160.

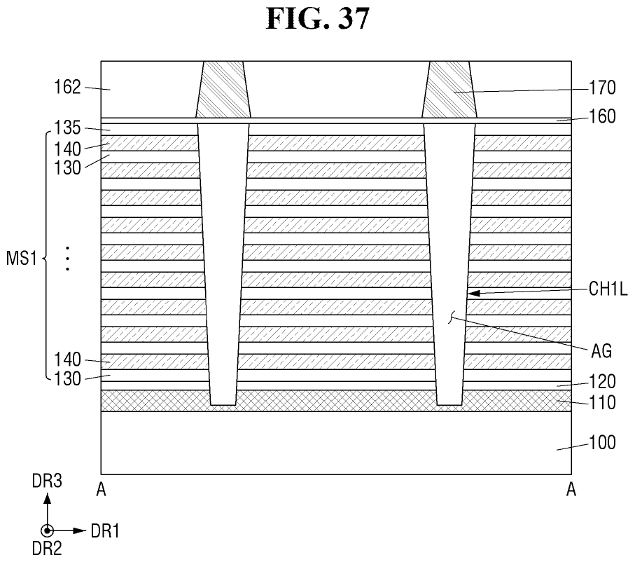

In some embodiments, unlike shown, the width W34 of the first upper channel hole CH1H at a boundary between the first middle channel hole CH1M and the first upper channel hole CH1H may be larger or smaller than a width W33 of the first lower channel hole CH1L at a boundary between the first lower channel hole CH1L and the first middle channel hole CH1M. This may be due to a manufacturing method for forming the etching stopper film 170 in FIG. 37, which will be described later.

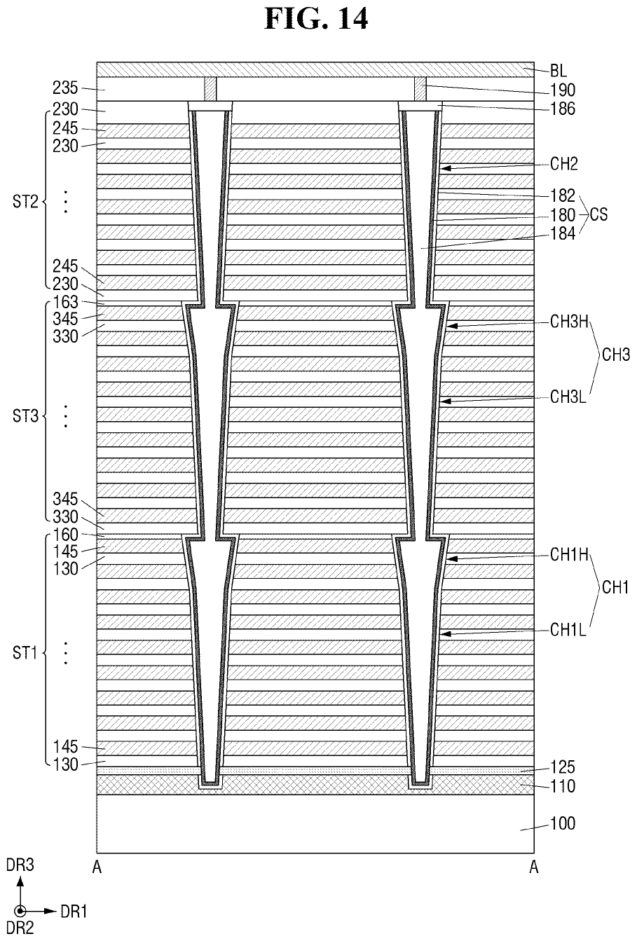

Referring to FIG. 14, unlike FIG. 3, a semiconductor device according to some embodiments may further include a third stack structure ST3 disposed between the first stack structure ST1 and the second stack structure ST2.

The third stack structure ST3 may include a plurality of third inter-electrode insulating films 330, and a plurality of third gate electrodes 345 alternately stacked one on top of another in the third direction DR3, and a third interlayer insulating film 163. The third inter-electrode insulating film 330 may be disposed between adjacent two third gate electrodes 345 spaced from each other in the third direction DR3. Each of the third inter-electrode insulating film 330 and the third gate electrode 345 may have a layered structure extending in the first direction DR1 and the second direction DR2. The third interlayer insulating film 163 may be disposed on the topmost portion of the third stack structure ST3 in the third direction DR3.

The third gate electrode 345 may, for example, include a conductive material. For example, the third gate electrode 345 may include a metal such as tungsten (W), cobalt (Co), nickel (Ni), and/or a semiconductor material such as silicon. However, the present disclosure is not limited thereto. The third inter-electrode insulating film 330 may include an insulating material. For example, the third inter-electrode insulating film 330 may include silicon oxide. However, the present disclosure is not limited thereto. The third interlayer insulating film 163 may include an oxide film ALD-OX formed using an atomic layer deposition process at room temperature. However, the present disclosure is not limited thereto.

The channel hole CH may further include a third channel hole CH3 extending through the third stack structure ST3. The third channel hole CH3 may include a third lower channel hole CH3L extending through a lower portion of the third stack structure ST3 and thus through some of the third gate electrodes 345, and a third upper channel hole CH3H extending through an upper portion of the third stack structure ST3 and thus extending through the other of the third gate electrodes 345. The third upper channel hole CH3H may extend through the third interlayer insulating film 163. The second channel hole CH2, the third upper channel hole CH3H, the third lower channel hole CH3L, the first upper channel hole CH1H, and the first lower channel hole CH1L may be sequentially arranged and connected to each other.

A side wall of the third channel hole CH3 may have an inclination change at a boundary between the third lower channel hole CH3L and the third upper channel hole CH3H. An inclination of a side wall of the third lower channel hole CH3L relative to the third direction DR3 may be smaller than an inclination of a side wall of the third upper channel hole CH3H.

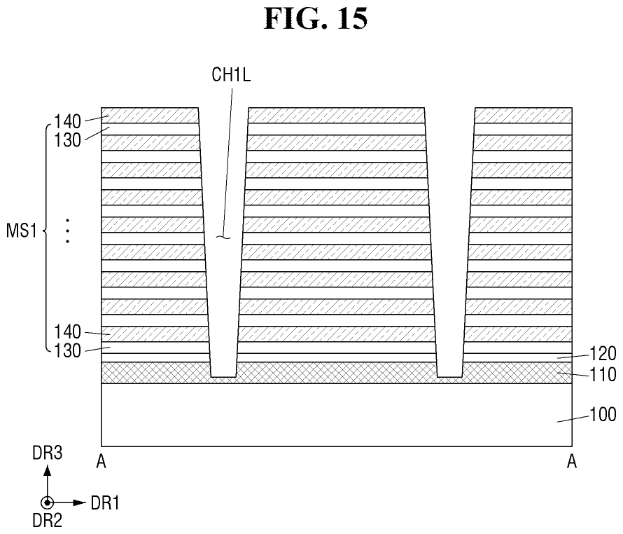

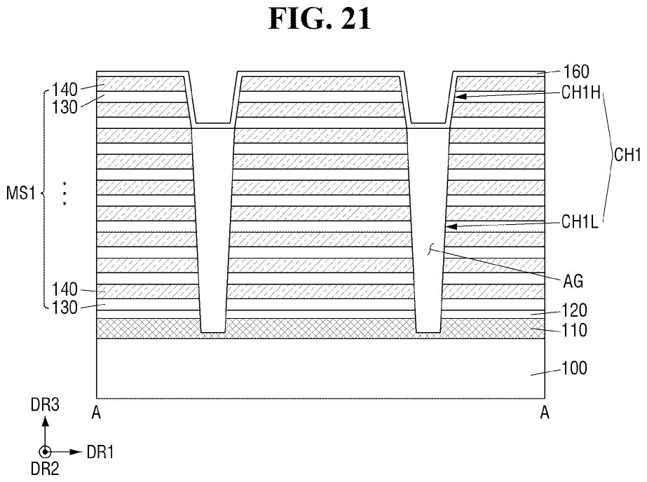

FIG. 15 to FIG. 27 are diagrams of intermediate structures to illustrate a method for manufacturing a semiconductor device according to some embodiments. For reference, FIG. 15 to FIG. 27 may correspond to cross-sectional views taken along a line A-A in FIG. 2.

Referring to FIG. 15, the source conductive layer 110 and a replaceable insulating film 120 may be sequentially formed on the substrate 100. A first mold structure MS1 in which the first inter-electrode insulating films 130 and first mold sacrificial films 140 are alternately stacked one on top of another in the third direction DR3 may be formed on the replaceable insulating film 120.

The first lower channel hole CH1L may be formed in the first mold structure MS1. The first lower channel hole CH1L may be formed by, for example, a dry etching process.

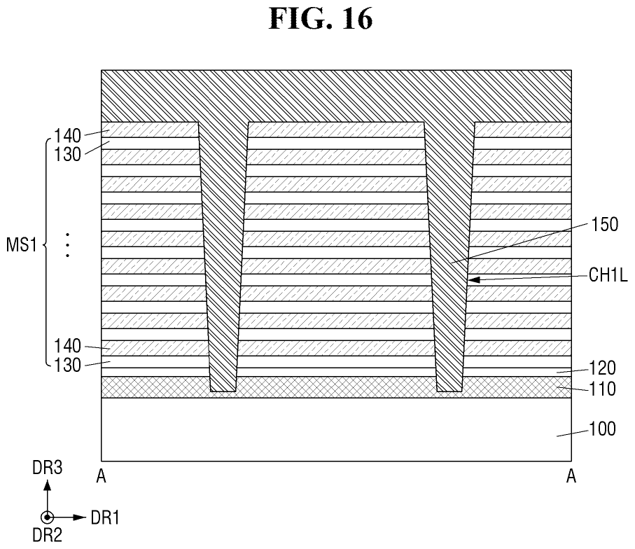

Referring to FIG. 16, a first sacrificial film 150 filling the first lower channel hole CH1L may be formed on the first mold structure MS1. The first sacrificial film 150 may be formed on a top face of the first mold sacrificial film 140 while filling the first lower channel hole CH1L. The first sacrificial film 150 may be, for example, a silicon-based or carbon-based spin on hard mask (SOH) material and may be formed by a spin coating process.

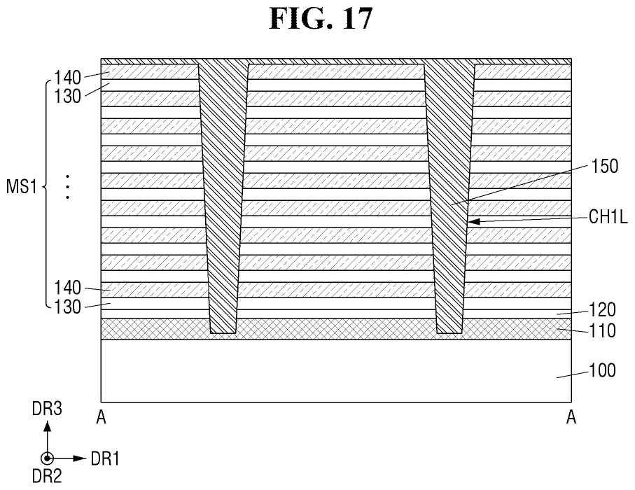

Referring to FIG. 17, a bake process may be performed on the first sacrificial film 150. Accordingly, the first sacrificial film 150 may shrink.

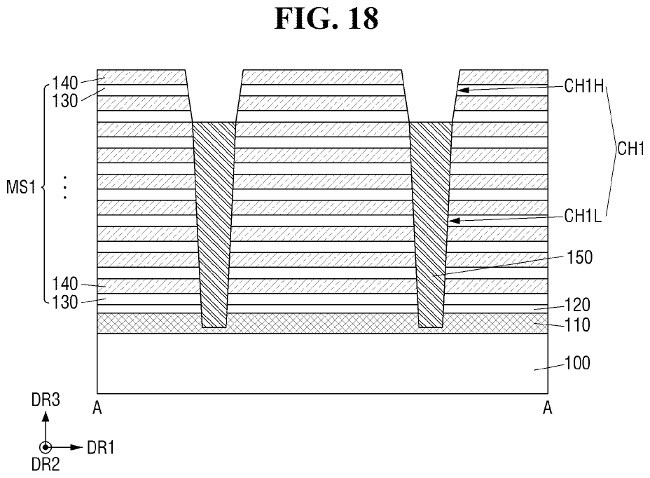

Referring to FIG. 18, the first sacrificial film 150 on the top face of the first mold structure MS1 and the first sacrificial film 150 filling an upper portion of the first lower channel hole CH1L may be removed. For example, the first sacrificial film 150 may be removed by a dry etching process. In this process, a portion of the first mold structure ST1 may be etched together therewith, so that the first upper channel hole CH1H may be formed. Accordingly, the first channel hole CH1 may be formed.

Further, the dummy hole DH in the scribe lane area SL in FIG. 3 may be formed simultaneously with the first channel hole CH1.

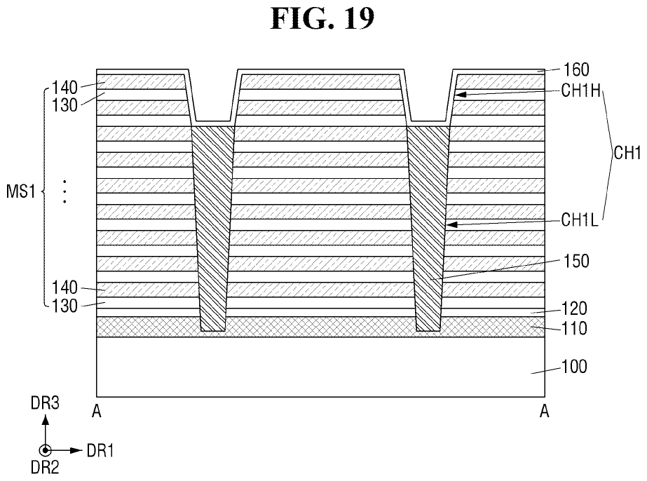

Referring to FIG. 19, the first interlayer insulating film 160 may be formed along a profile of the first upper channel hole CH1H and a top face of the first sacrificial film 150. The first interlayer insulating film 160 may be formed along a top face of the first mold sacrificial film 140, a side wall of the first upper channel hole CH1H, and a top face of the first sacrificial film 150.

Further, the first interlayer insulating film 160 may be formed along a profile of the dummy hole DH in the scribe lane area SL of FIG. 3 and a top face of the first filling oxide film 132.

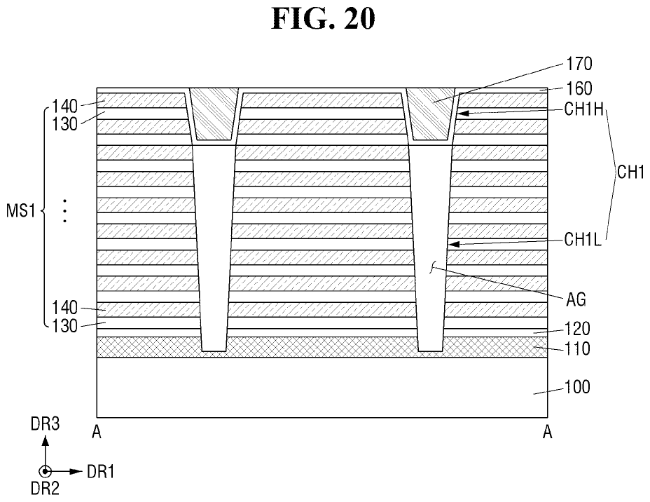

Referring to FIG. 20, the first sacrificial film 150 in the first lower channel hole CH1L may be removed. The first interlayer insulating film 160 may be, for example, an oxide film ALD-OX having a thickness of 10 nm or smaller and formed by an atomic layer deposition process at room temperature, and may not be sufficiently hard. Therefore, the first sacrificial film 150 may be removed by an ashing process. Accordingly, an air gap AG may be formed in the first lower channel hole CH1L. The air gap AG may be defined by a side wall of the first lower channel hole CH1L and a bottom face of the first interlayer insulating film 160.

Further, the air gap AG may be formed in the lower dummy hole DHL of the scribe lane area SL in FIG. 3.

Referring to FIG. 20, the etching stopper film 170 filling the first upper channel hole CH1H may be formed on the first interlayer insulating film 160. For example, after the etching stopper film 170 is formed to cover or overlap a top face of the first interlayer insulating film 160, the etching stopper film 170 may be planarized until the top face of the first interlayer insulating film 160 on the first mold sacrificial film 140 is exposed by a planarization process.

The etching stopper film 170 may be made of a material having an etching selectivity to oxide and nitride. The etching stopper film 170 may include, for example, polysilicon, AlO, and the like. However, the present disclosure is not limited thereto. In some embodiments, the etching stopper film 170 may include, for example, a metal material. The etching stopper film 170 may include, for example, TiN, W, and the like. However, the present disclosure is not limited thereto.

Further, the etching stopper film 170 filling or at least partially filling the lower dummy hole DHL of the scribe lane area SL in FIG. 3 may be formed.

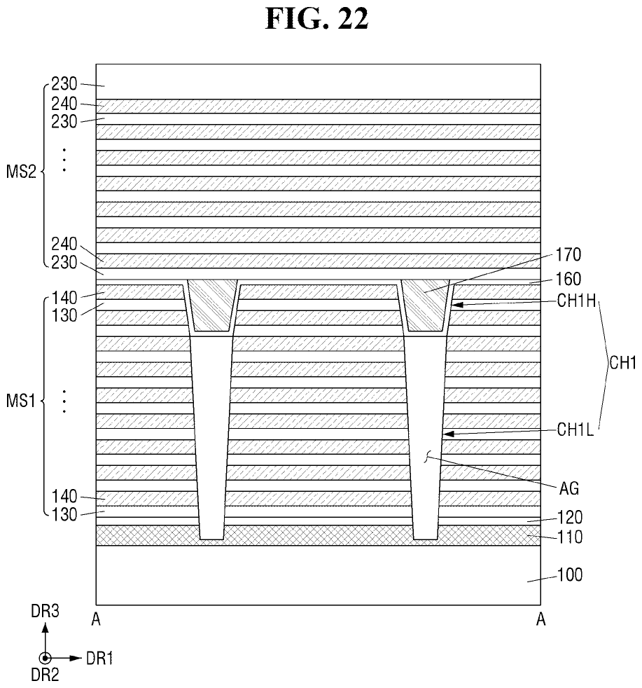

Referring to FIG. 22, a second mold structure MS2 may be formed on the first interlayer insulating film 160 and the etching stopper film 170. The second mold structure MS2 may have a structure in which the second inter-electrode insulating films 230 and second mold sacrificial films 240 are alternately stacked one on top of another in the third direction DR3.

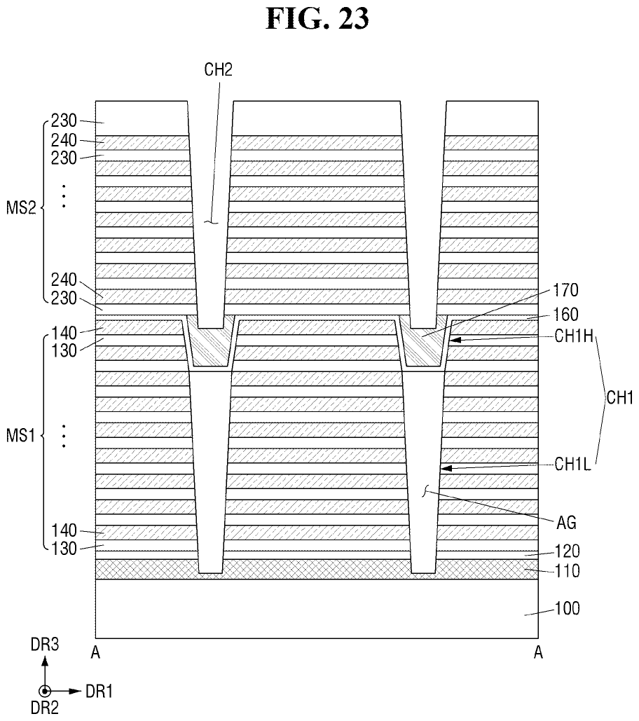

Referring to FIG. 23, the second channel hole CH2 may be formed in the second mold structure MS2. The second channel hole CH2 may be formed by, for example, a dry etching process. The second channel hole CH2 may partially extend through an upper portion of the etching stopper film 170.

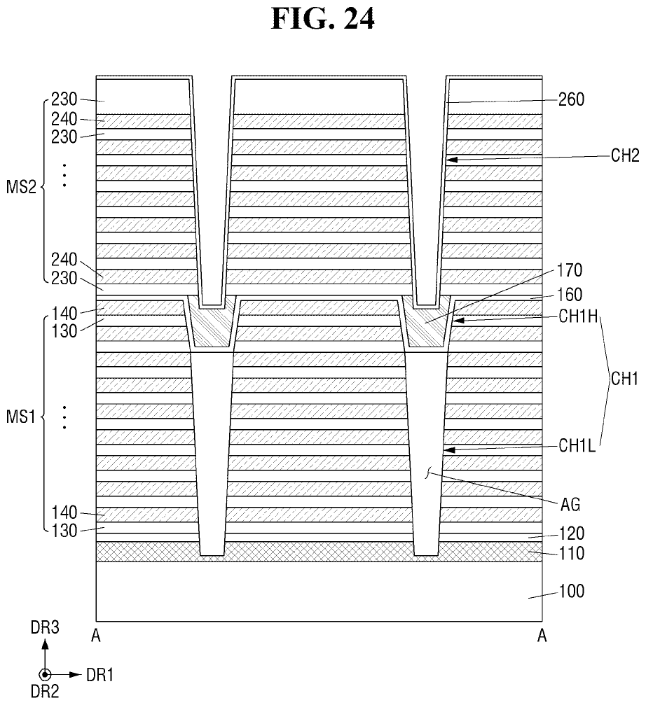

Referring to FIG. 24, the second interlayer insulating film 260 may be formed along a profile of the second channel hole CH2 and a top face of the second mold structure MS2. The second interlayer insulating film 260 may be formed along a top face of the second inter-electrode insulating film 230, and a side wall and a bottom face of the second channel hole CH2.

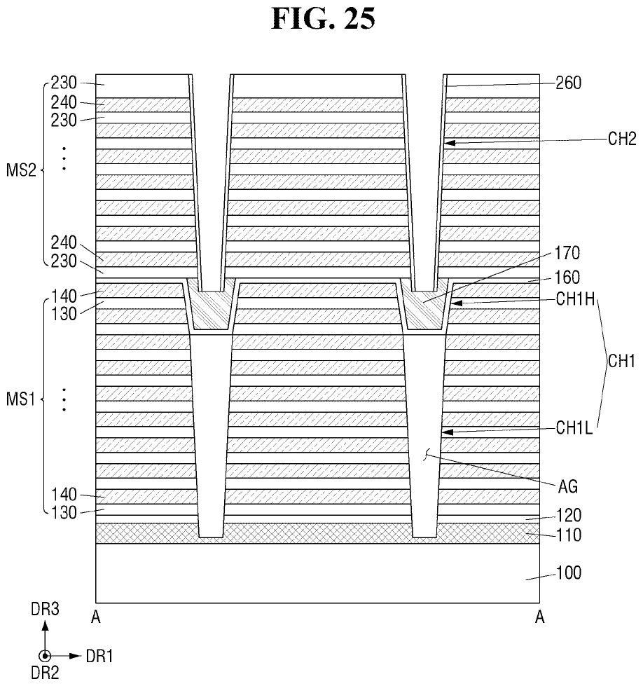

Referring to FIG. 25, the second interlayer insulating film 260 on the top face of the second inter-electrode insulating film 230 and the second interlayer insulating film 260 on the bottom face of the second channel hole CH2 may be removed. For example, the second interlayer insulating film 260 may be removed by an etch back process. Accordingly, the top face of the etching stopper film 170 may be exposed.

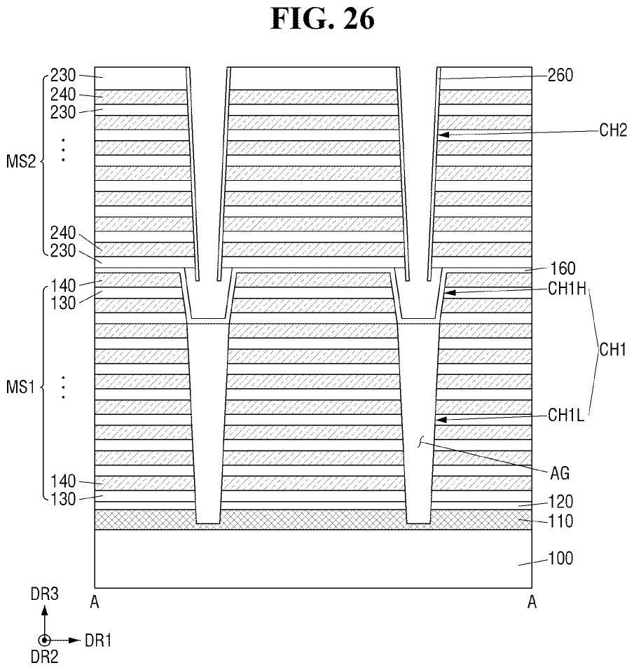

Referring to FIG. 26, the etching stopper film 170 may be removed through the second channel hole CH2. The etching stopper film 170 may be removed by, for example, a wet etching process. Accordingly, the first interlayer insulating film 160 defining the air gap AG in the first upper channel hole CH1H may be exposed.

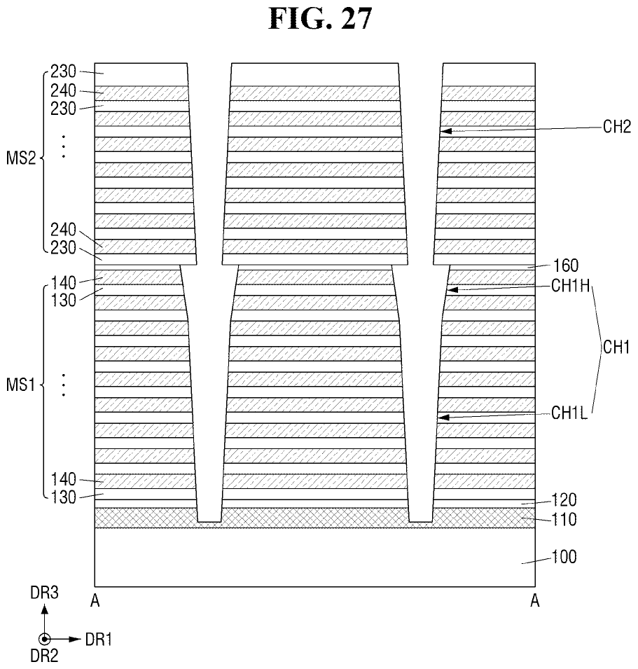

Referring to FIG. 27, the second interlayer insulating film 260 formed along the side wall of the second channel hole CH2, the first interlayer insulating film 160 formed along the side wall of the first upper channel hole CH1H, and the first interlayer insulating film 160 defining the air gap AG may be removed. For example, the first interlayer insulating film 160 and the second interlayer insulating film 260 may be removed by a wet etching process. Accordingly, both the first interlayer insulating film 160 and the second interlayer insulating film 260 in the first channel hole CH1 and the second channel hole CH2 may be removed. In this connection, the second interlayer insulating film 260 formed on the side wall of the second channel hole CH2 may prevent the second inter-electrode insulating film 230 in the second mold structure MS2 from being etched away.

Subsequently, referring to FIG. 3, the channel structure CS may be formed in the channel hole CH. A portion of the channel structure CS may be removed such that the bit line pad 186 may be formed in the channel hole CH.

Subsequently, the upper insulating film 235 may be formed on the bit line pad 186.

Subsequently, a cutting line trench (not shown) extending through the first mold structure MS1, the first interlayer insulating film 160 and the second mold structure MS2 may be formed. The replaceable insulating film 120 may be removed through the cutting line trench. The support layer 125 may be formed in a space from which the replaceable insulating film 120 has been removed. In this connection, the channel insulating film 182 under the channel structure CS may be removed to expose the channel film 180. The support layer 125 may be formed in a space where the channel insulating film 182 has been removed. Thus, the channel film 180 and the source conductive layer 110 may be electrically connected to each other.

The first mold sacrificial film 140 and the second mold sacrificial film 240 may be removed through the cutting line trench. The first gate electrode 145 may be formed in a space where the first mold sacrificial film 140 has been removed. The second gate electrode 245 may be formed in a space where the second mold sacrificial film 240 has been removed.

In other words, the first mold sacrificial film 140 and the second mold sacrificial film 240 may be replaced with the first gate electrode 145 and the second gate electrode 245, respectively, by a replacement metal gate process.

Subsequently, the bit line plug 190 and the bit line BL may be formed.

After forming a sacrificial pattern in the first channel hole CH1, the second channel hole CH2 may be formed using the sacrificial pattern as an etching stopper film. When the sacrificial pattern includes polysilicon, the second channel hole CH2 may be partially formed into the sacrificial pattern. Accordingly, an insulating film having a certain thickness and disposed between the first stack structure ST1 and the second stack structure ST2 is required. Due to the thickness of the insulating film, current flowing through the channel hole CH may be degraded.

Further, when the sacrificial pattern is removed after the second channel hole CH2 is formed, the sacrificial pattern may not be completely removed because a diameter of the second channel hole CH2 is small. When the sacrificial pattern includes polysilicon as an electrically-conductive material, a bridge between the gate electrodes 145 and 245 may be formed due to the polysilicon.

However, in a method for manufacturing a semiconductor device according to some embodiments, the second channel hole CH2 may be formed while the air gap AG is formed in the first channel hole CH1. Therefore, since the sacrificial pattern in the first channel hole CH1 does not exist, the bridge formation between the gate electrodes 145 and 245 due to the sacrificial pattern remaining in the first channel hole CH1 may be prevented. Further, since the second channel hole CH2 is formed using the etching stopper film 170 including a material having an etching selectivity to oxides and nitrides, an insulating film having a certain thickness and disposed between the first stack structure ST1 and the second stack structure ST2 may not be required, thereby preventing the deterioration of the current flowing through the channel hole CH.

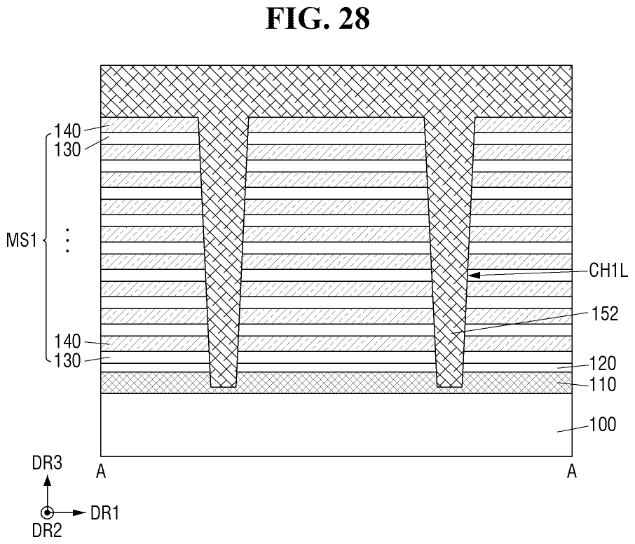

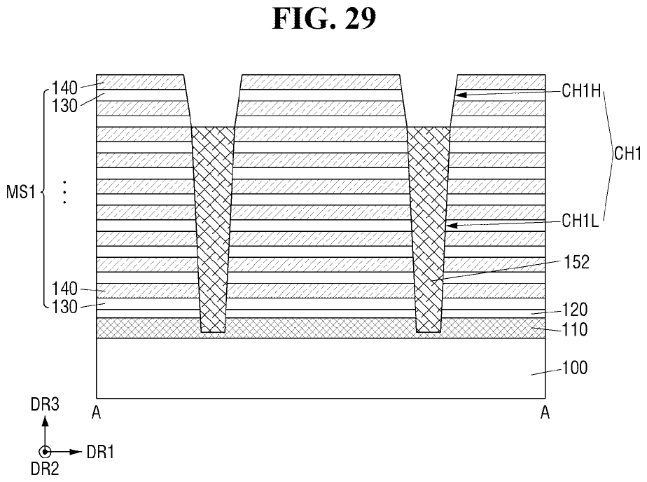

FIG. 28 and FIG. 29 are diagrams of intermediate structures to illustrate a method for manufacturing a semiconductor device according to some embodiments. For reference, FIG. 28 and FIG. 29 may correspond to cross-sectional views taken along a line A-A of FIG. 2. FIG. 28 is a diagram after the process of FIG. 15.

Referring to FIG. 28, a second mold sacrificial film 240 or 152 filling the first lower channel hole CH1L may be formed on the first mold structure MS1. The second mold sacrificial film 240 or 152 may be formed on a top face of the first mold sacrificial film 140 while filling the first lower channel hole CH1L. The second mold sacrificial film 240 or 152 may include carbon in one example, and may be formed by a coating process at high temperature of 500 degrees C. or higher. Accordingly, the baking process in FIG. 17 may be omitted, and the shrinkage of the second mold sacrificial film 240 or 152 may not occur.

Referring to FIG. 29, the second mold sacrificial film 240 or 152 on the top face of the first mold structure MS1 and the second mold sacrificial film 240 or 152 filling the upper portion of the first lower channel hole CH1L may be removed. For example, the second mold sacrificial film 240 or 152 may be removed by a dry etch back process. In this process, a portion of the first mold structure ST1 may be etched away together therewith, so that the first upper channel hole CH1H may be formed. Since the dry etch back process is performed without shrinking the second mold sacrificial film 240 or 152, the first upper channel hole CH1H having a more uniform profile may be formed.

Subsequently, a process of FIG. 19 may be performed.

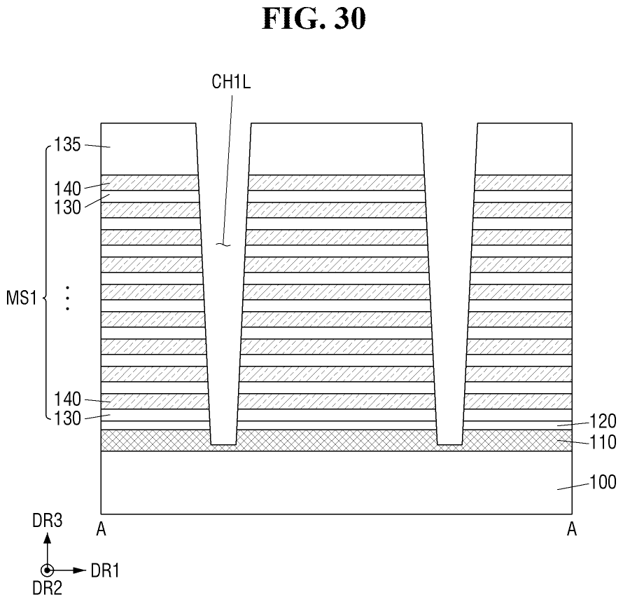

FIG. 30 to FIG. 33 are diagrams of intermediate structures to illustrate a method for manufacturing a semiconductor device according to some embodiments. For reference, FIG. 30 to FIG. 33 may cross-sectional views taken along a line A-A in FIG. 2.

Referring to FIG. 30, the source conductive layer 110 and the replaceable insulating film 120 may be sequentially formed on the substrate 100. A first mold structure MS1 in which the first inter-electrode insulating films 130 and the first mold sacrificial films 140 are alternately stacked one on top of another in the third direction DR3 may be formed on the replaceable insulating film 120. A thickness of the topmost first inter-electrode insulating film 135 of the first mold structure MS1 in the third direction DR3 may be larger than each of that of each of other first inter-electrode insulating films 130 and that of the second inter-electrode insulating film 230.

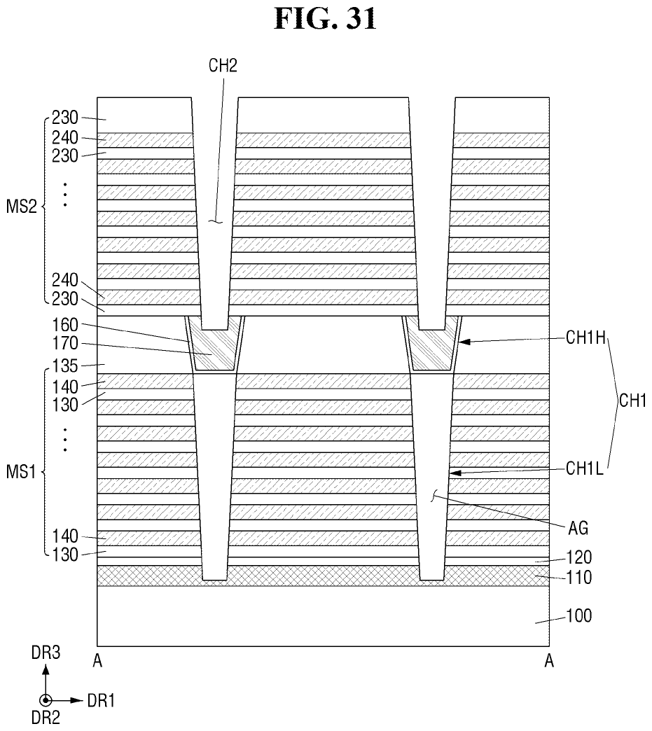

Subsequently, the processes of FIG. 16 to FIG. 23 may be performed. Accordingly, the semiconductor device shown in FIG. 31 may be formed.

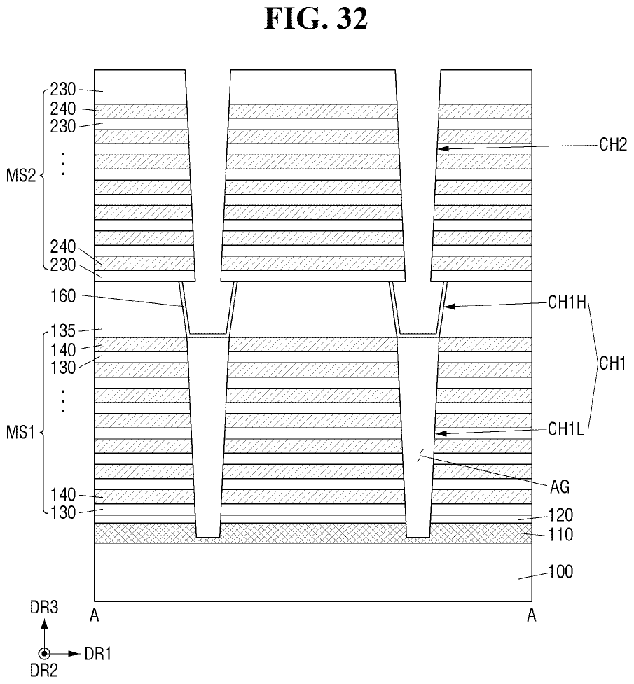

Subsequently, referring to FIG. 32, the etching stopper film 170 may be removed through the second channel hole CH2. The etching stopper film 170 may be removed by, for example, a wet etching process. Accordingly, the first interlayer insulating film 160 defining the air gap AG in the first upper channel hole CH1H may be exposed. That is, the processes of FIG. 24 and FIG. 25 may be omitted.

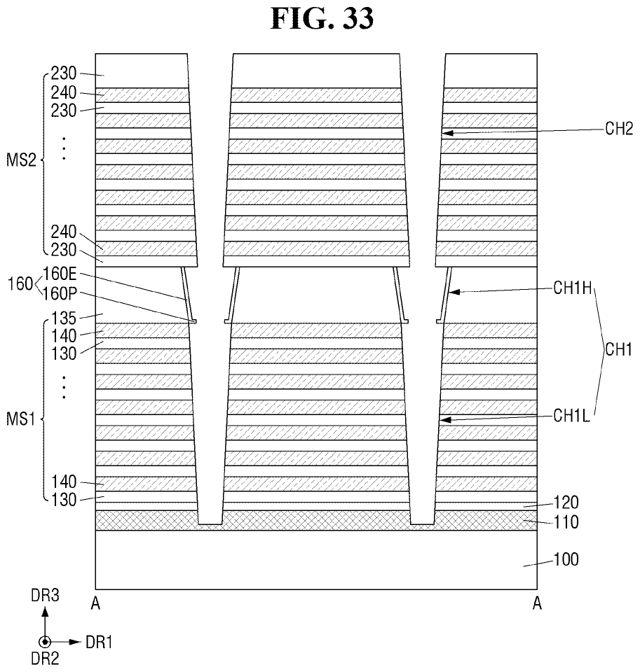

Referring to FIG. 33, a portion of the first interlayer insulating film 160 exposed through the second channel hole CH2 may be removed through the second channel hole CH2. For example, the portion of the first interlayer insulating film 160 may be removed by an etch back process. Accordingly, a portion of the first interlayer insulating film 160 that is not exposed through the second channel hole CH2 may not be removed so that a protruding portion 160P1 may be formed.

Subsequently, referring to FIG. 11, the channel structure CS and the bit line pad 186 may be formed in the channel hole CH. The upper insulating film 235, the support layer 125, the first gate electrode 145, the second gate electrode 245, the bit line plug 190, and the bit line BL may be formed.

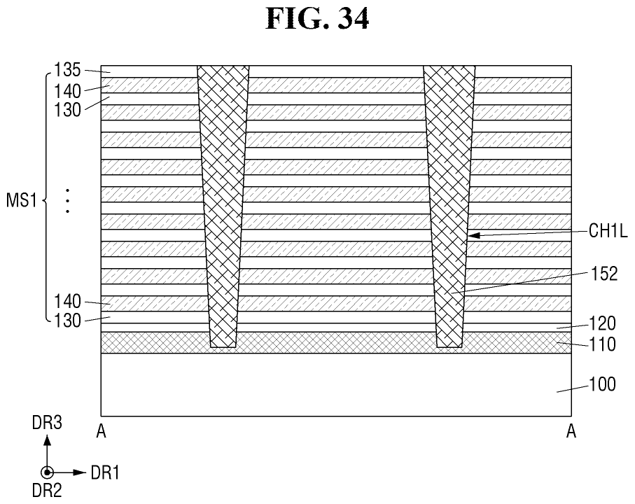

FIG. 34 to FIG. 41 are diagrams of intermediate structures to illustrate a method for manufacturing a semiconductor device according to some embodiments. For reference, FIG. 34 to FIG. 41 may correspond to cross-sectional views taken along a line A-A in FIG. 2. FIG. 34 is a diagram after the process of FIG. 30.

Referring to FIG. 34, the second mold sacrificial film 240 or 152 filling or at least partially filling the first lower channel hole CH1L may be formed on the first mold structure MS1. The second mold sacrificial film 240 or 152 may be formed on the top face of the first mold sacrificial film 140 while filling the first lower channel hole CH1L. The second mold sacrificial film 240 or 152 may include carbon in one example, and may be formed by a coating process at high temperature of 500 degrees C. or higher.

Subsequently, top faces of the first inter-electrode insulating film 135 and the second mold sacrificial film 240 or 152 may be coplanar with each other by a planarization process.

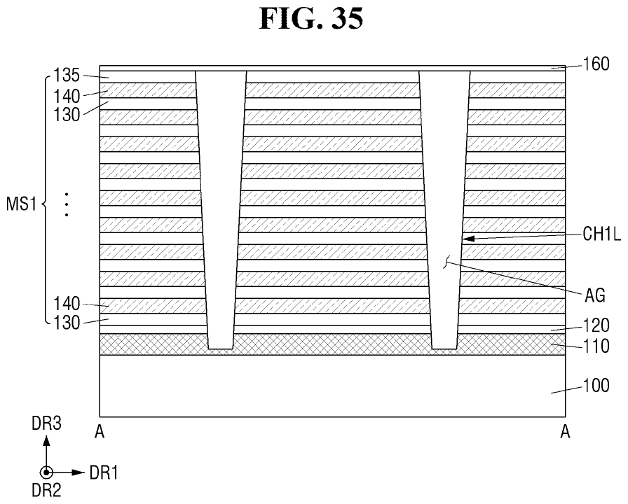

Referring to FIG. 35, the first interlayer insulating film 160 may be formed on the planarized top faces of the first inter-electrode insulating film 135 and the second mold sacrificial film 240 or 152.

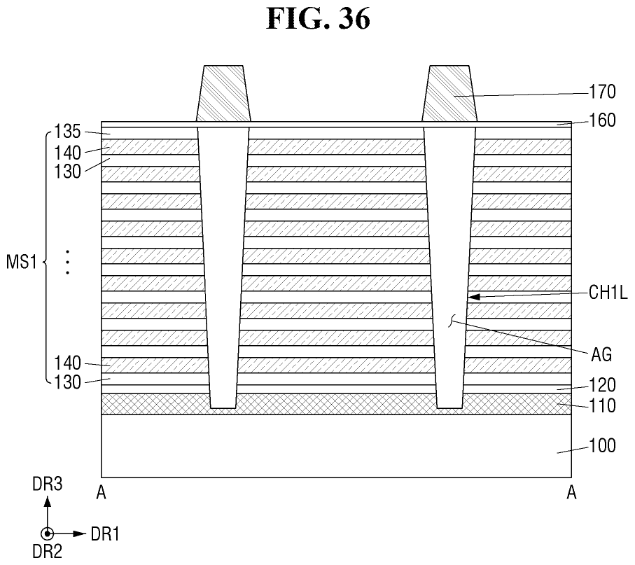

Referring to FIG. 36, the etching stopper film 170 may be formed on the first interlayer insulating film 160. The etching stopper film 170 may be formed by, for example, a patterning process. Accordingly, a width in the first direction DR1 of the etching stopper film 170 may decrease as it extends in a direction away from the substrate 100. Further, due to misalignment of a mask pattern (not shown), a width in the first direction DR1 of a bottom face of the etching stopper film 170 may be greater or smaller than a width in the first direction DR1 of the first lower channel hole CH1L.

Referring to FIG. 37, the second interlayer insulating film 162 may be formed on the first interlayer insulating film 160. The second interlayer insulating film 162 may expose a top face of the etching stopper film 170.

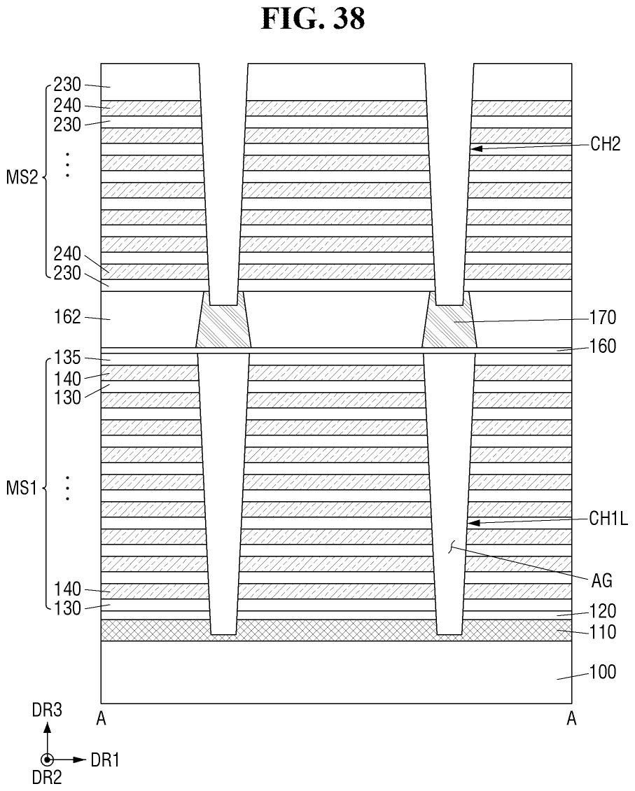

Referring to FIG. 38, a second mold structure MS2 in which the second inter-electrode insulating films 230 and second mold sacrificial films 240 are alternately stacked one on top of another in the third direction DR3 may be formed on the second interlayer insulating film 162. The second channel hole CH2 may be formed in the second mold structure MS2.

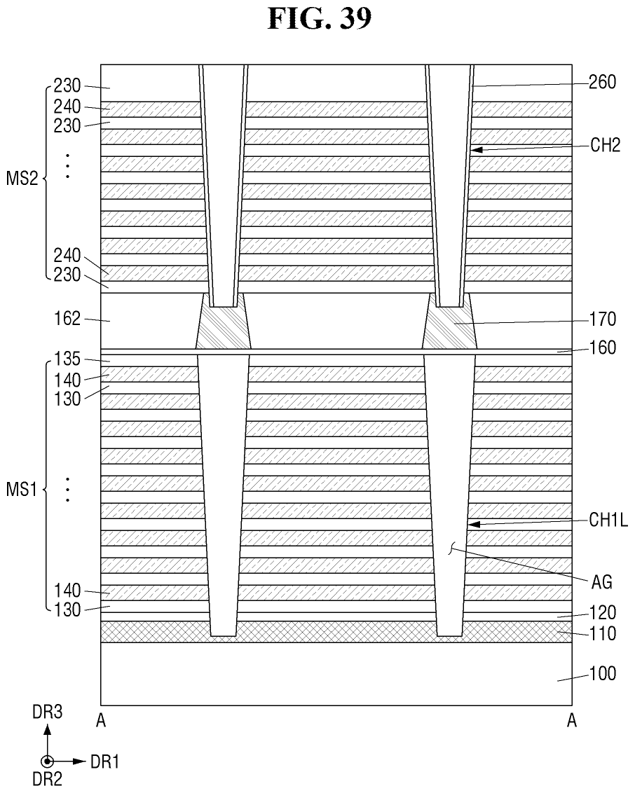

Referring to FIG. 39, the second interlayer insulating film 260 may be formed along a profile of the second channel hole CH2 and a top face of the second mold structure MS2. The second interlayer insulating film 260 may be formed along a top face of the second inter-electrode insulating film 230 and the side wall and the bottom face of the second channel hole CH2. The second interlayer insulating film 260 on the top face of the second inter-electrode insulating film 230 and the second interlayer insulating film 260 on the bottom face of the second channel hole CH2 may be removed. For example, the second interlayer insulating film 260 may be removed by an etch back process. Accordingly, a top face of the etching stopper film 170 may be exposed.

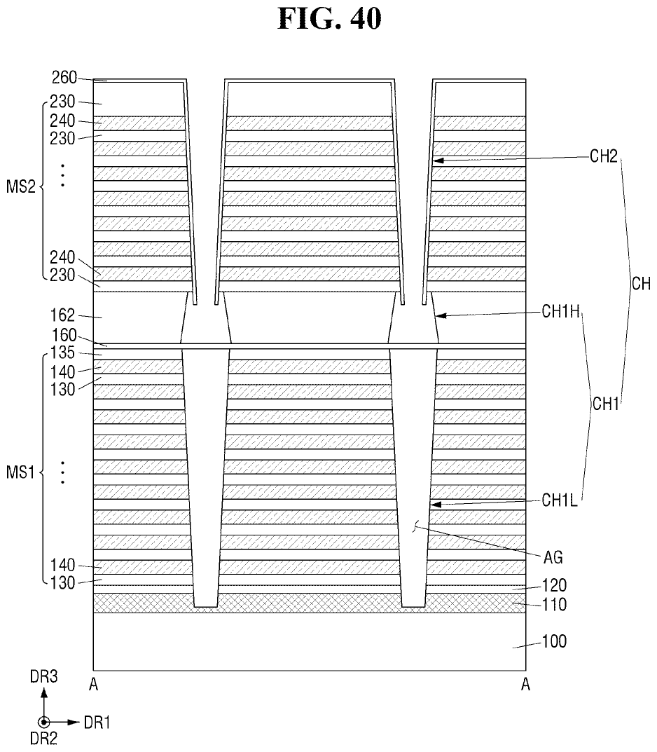

Referring to FIG. 40, the etching stopper film 170 may be removed through the second channel hole CH2. The etching stopper film 170 may be removed by, for example, a wet etching process. Accordingly, a top face of the first interlayer insulating film 160 may be exposed.

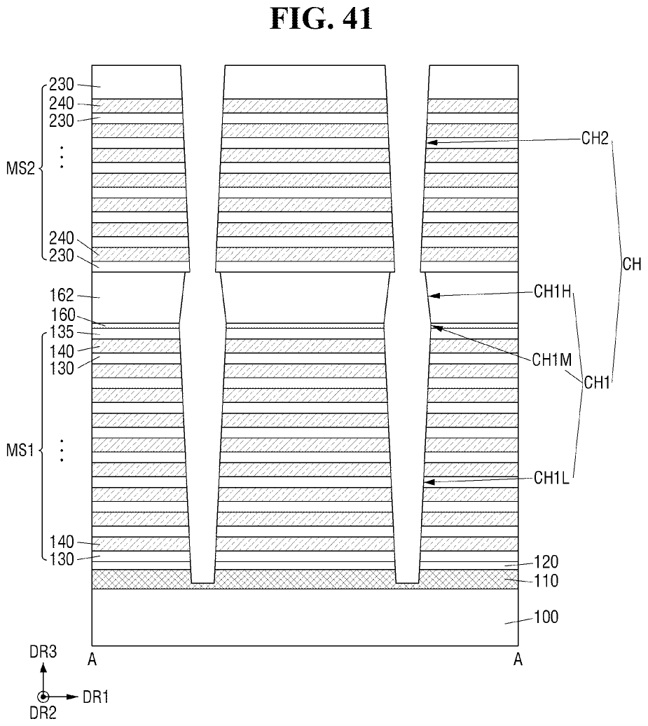

Referring to FIG. 41, the second interlayer insulating film 260 formed along the side wall of the second channel hole CH2 and the exposed first interlayer insulating film 160 may be removed. As the first interlayer insulating film 160 is removed, the first middle channel hole CH1M defined by the first interlayer insulating film 160 may be formed. For example, the first interlayer insulating film 160 and the second interlayer insulating film 260 may be removed by a wet etching process. Accordingly, both the first interlayer insulating film 160 and the second interlayer insulating film 260 in the first channel hole CH1 and the second channel hole CH2 may be removed.

Subsequently, referring to FIG. 12, the channel structure CS and the bit line pad 186 may be formed in the channel hole CH. The upper insulating film 235, the support layer 125, the first gate electrode 145, the second gate electrode 245, the bit line plug 190, and the bit line BL may be formed.

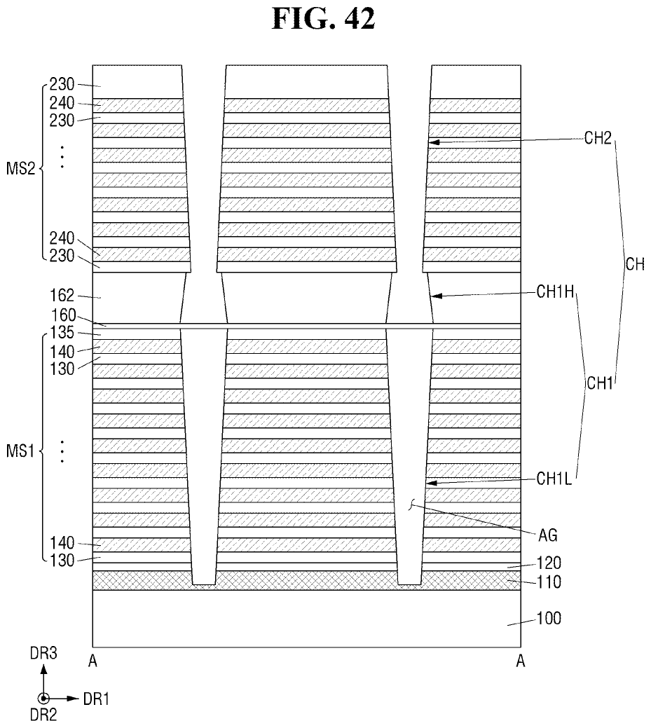

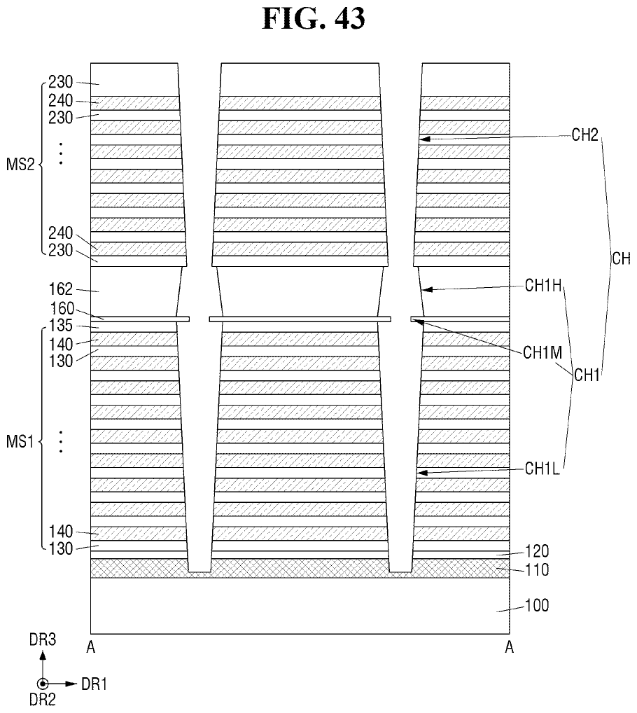

FIG. 42 and FIG. 43 are diagrams of intermediate structures to illustrate a method for manufacturing a semiconductor device according to some embodiments. For reference, FIG. 42 and FIG. 43 may correspond to cross-sectional views taken along a line A-A of FIG. 2. FIG. 42 is a diagram after the process of FIG. 38.

Referring to FIG. 42, the etching stopper film 170 may be removed through the second channel hole CH2. The etching stopper film 170 may be removed by, for example, a wet etching process. Accordingly, a top face of the first interlayer insulating film 160 may be exposed.

Referring to FIG. 43, a portion of the first interlayer insulating film 160 exposed through the second channel hole CH2 may be removed. For example, the portion of the first interlayer insulating film 160 may be removed by an etch back process. Accordingly, a portion of the first interlayer insulating film 160 that is not exposed through the second channel hole CH2 may not be removed so that a protruding portion 160P2 may be formed.

Subsequently, referring to FIG. 13, the channel structure CS and the bit line pad 186 may be formed in the channel hole CH. The upper insulating film 235, the support layer 125, the first gate electrode 145, the second gate electrode 245, the bit line plug 190, and the bit line BL may be formed.

FIG. 44 is a schematic diagram of an electronic system including a semiconductor device according to some embodiments.

In FIG. 44, an electronic system 1000 including a semiconductor device according to some embodiments may include a semiconductor device 1100 and a controller 1200 that is electrically connected to the semiconductor device 1100. The electronic system 1000 may be embodied as a storage device including one or a plurality of semiconductor devices 1100 or an electronic device including the storage device. For example, the electronic system 1000 may be embodied as an SSD device (a solid state drive device), a USB (Universal Serial Bus), a computing system, a medical device, or a communication device, each including one or a plurality of semiconductor devices 1100.

The semiconductor device 1100 may be a nonvolatile memory device. For example, the semiconductor device 1100 may be the semiconductor device as described above with reference to FIGS. 1 to 14. The semiconductor device 1100 may include a first structure 110F and a second structure 1100S on the first structure 110F. In example embodiments, the first structure 110F may be disposed horizontally adjacent to the second structure 1100S. The first structure 110F may be embodied as a peripheral circuit structure including a decoder circuit 1110, a page buffer 1120, and a logic circuit 1130. The second structure 1100S may be embodied as a memory cell structure including the bit line BL, a common source line CSL, word lines WL, first and second gate upper lines UL1 and UL2, first and second gate lower lines LL1, LL2, and memory cell strings CSTR between the bit line BL and the common source line CSL. The common source line CSL may correspond to the source conductive layer 110 described above with reference to FIGS. 1 to 14. The word lines WL, the first and second gate upper lines UL1 and UL2, and the first and second gate lower lines LL1 and LL2 may correspond to the first and second gate electrodes 145 and 245 described above with reference to FIGS. 1 to 14.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary according to embodiments.

In example embodiments, each of the upper transistors UT1 and UT2 may include a string selection transistor. Each of the lower transistors LT1 and LT2 may include a ground selection transistor. The gate lower lines LL1 and LL2 may act as gate electrodes of the lower transistors LT1 and LT2, respectively. The word lines WL may act as gate electrodes of the memory cell transistors MCT, respectively. The gate upper lines UL1 and UL2 may act as gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 via first connection wires 1115 extending from the first structure 110F to the second structure 1100S. The bit lines BL may be electrically connected to the page buffer 1120 via second connection wires 1125 extending from the first structure 110F to the second structure 1100S.

In the first structure 110F, the decoder circuit 1110 and the page buffer 1120 may perform a control operation on at least one selection memory cell transistor among the plurality of memory cell transistors MCTs. The decoder circuit 1110 and the page buffer 1120 may be controlled by the logic circuit 1130. The semiconductor device 1100 may communicate with the controller 1200 via an input/output pad 1101 that is electrically connected to the logic circuit 1130. The input/output pad 1101 may be electrically connected to the logic circuit 1130 via an input/output connection wire 1135 extending from the first structure 110F to the second structure 1100S.

The controller 1200 may include a processor 1210, a NAND controller 1220, and a host interface 1230. Depending on embodiments, the electronic system 1000 may include a plurality of semiconductor devices 1100. In this case, the controller 1200 may control a plurality of semiconductor devices 1100.

The processor 1210 may control operations of the electronic system 1000 including the controller 1200. The processor 1210 may operate according to predefined firmware. The processor 1210 may control the NAND controller 1220 to access the semiconductor device 1100. The NAND controller 1220 may include a NAND interface 1221 that processes communication with the semiconductor device 1100. Control commands to control the semiconductor device 1100, data to be written to the memory cell transistors MCT of the semiconductor device 1100, data to be read from the memory cell transistors MCT of the semiconductor device 1100, etc. may be transmitted via the NAND interface 1221. The host interface 1230 may provide a communication function between the electronic system 1000 and an external host. When the processor 1210 receives a control command from an external host via the host interface 1230, the processor 1210 may control the semiconductor device 1100 in response to the control command.

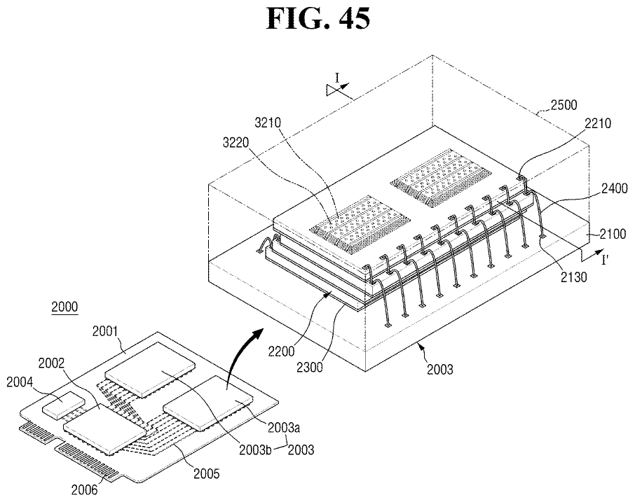

FIG. 45 is a schematic perspective view of an electronic system including a semiconductor device according to some embodiments.

Referring to FIG. 45, an electronic system 2000 according to an example implementation of the present disclosure may include a main substrate 2001, a controller 2002 mounted on the main substrate 2001, at least one semiconductor package 2003, and a DRAM 2004. The semiconductor package 2003 and the DRAM 2004 may be connected with the controller 2002 via wire patterns 2005 formed in the main substrate 2001.

The main substrate 2001 may include a connector 2006 including a plurality of pins coupled to an external host. The number and an arrangement of the plurality of pins in the connector 2006 may vary depending on a communication interface between the electronic system 2000 and the external host. In example embodiments, the electronic system 2000 may communicate with the external host according to one of interfaces such as USB (Universal Serial Bus), PCI-Express (Peripheral Component Interconnect Express), SATA (Serial Advanced Technology Attachment), and M-Phy for UFS (Universal Flash Storage). In example embodiments, the electronic system 2000 may operate using power supplied from the external host via the connector 2006. The electronic system 2000 may further include a PMIC (Power Management Integrated Circuit) that distributes the power supplied from the external host to the controller 2002 and the semiconductor package 2003.

The controller 2002 may write data to the semiconductor package 2003 or read data from the semiconductor package 2003 and may improve an operation speed of the electronic system 2000.

The DRAM 2004 may act as a buffer memory for mitigating a difference between operation speeds of the semiconductor package 2003 as a data storage space, and the external host. The DRAM 2004 which is included in the electronic system 2000 may act as a type of cache memory. In a control operation of the semiconductor package 2003, the DRAM 2004 may provide a space for temporarily storing data therein. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced from each other. Each of the first and second semiconductor packages 2003a and 2003b may refer to a semiconductor package including a plurality of semiconductor chips 2200. Each of the first and second semiconductor packages 2003a and 2003b may include a package substrate 2100, semiconductor chips 2200 on the package substrate 2100, an adhesive layer 2300 disposed on a bottom face of each of the semiconductor chips 2200, a connection structure 2400 electrically connecting the semiconductor chips 2200 and the package substrate 2100, and a molding layer 2500 disposed on the package substrate 2100 to or overlap the semiconductor chips 2200 and the connection structure 2400.

The package substrate 2100 may act as a printed circuit board including package upper pads 2130. Each semiconductor chip 2200 may include an input/output pad 2210. The input/output pad 2210 may correspond to the input/output pad 1101 in FIG. 44. Each of the semiconductor chips 2200 may include first and second stack structures 3210 and a channel structure 3220. Each of the semiconductor chips 2200 may include the semiconductor device as described above with reference to FIG. 1 to FIG. 14.

In example embodiments, the connection structure 2400 may be embodied as a bonding wire electrically connecting the input/output pad 2210 and the package upper pads 2130 to each other. Thus, in each of the first and second semiconductor packages 2003a and 2003b, the semiconductor chips 2200 may be electrically connected to each other in a bonding wire scheme and may be electrically connected to the package upper pads 2130 of the package substrate 2100. Depending on embodiments, in each of the first and second semiconductor packages 2003a and 2003b, the semiconductor chips 2200 may be electrically connected to each other via a connection structure 2400 including a through-electrode (through silicon via: TSV), instead of the bonding wire type connection structure 2400.

In example embodiments, the controller 2002 and the semiconductor chips 2200 may be included in a single package. In an example implementation, the controller 2002 and the semiconductor chips 2200 may be mounted on a separate interposer substrate different from the main substrate 2001. Then, the controller 2002 and the semiconductor chips 2200 may be connected to each other via a wire formed on the interposer substrate.

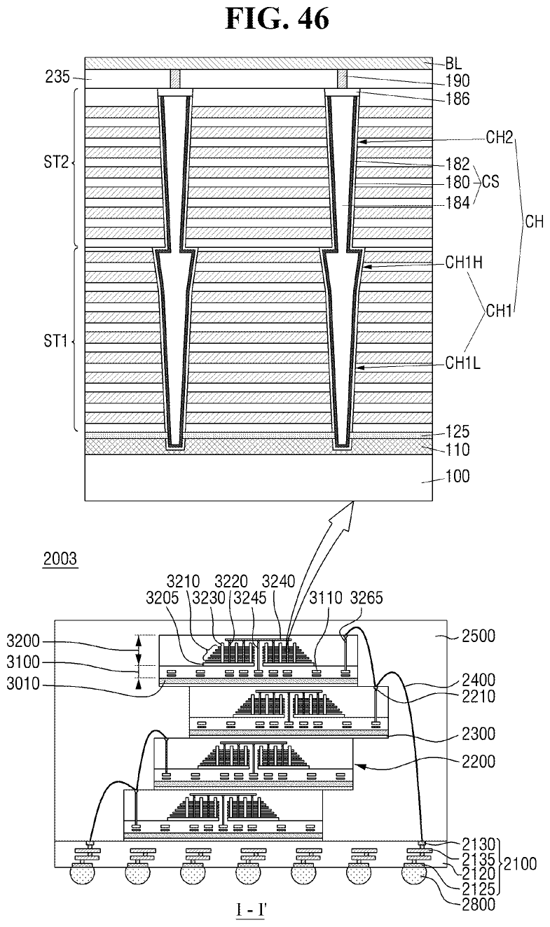

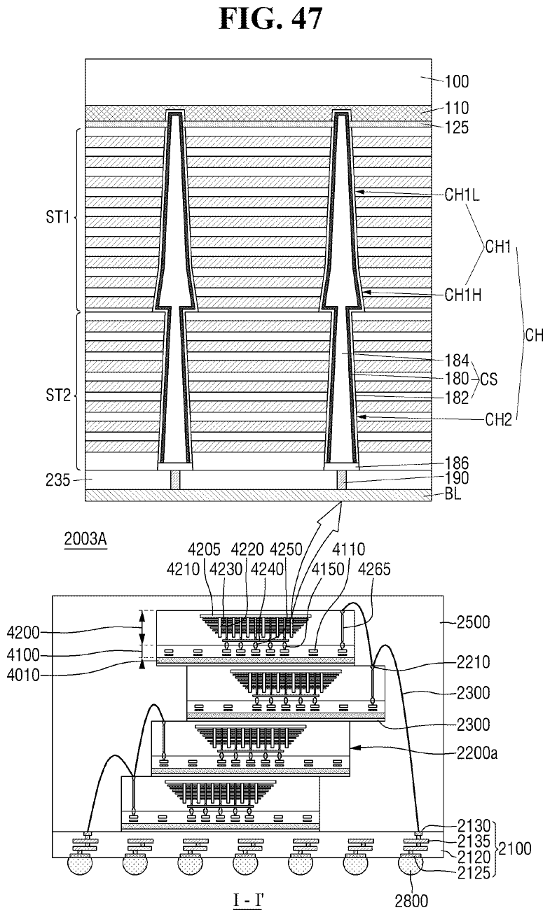

FIG. 46 and FIG. 47 are schematic cross-sectional views of semiconductor packages according to some embodiments. Each of FIG. 46 and FIG. 47 illustrates an example implementation of the semiconductor package 2003 in FIG. 45. An area cut along a cutting line I-I′ of the semiconductor package 2003 in FIG. 45 is conceptually shown in those drawings.

Referring to FIG. 46, in the semiconductor package 2003, the package substrate 2100 may be embodied as a printed circuit board. The package substrate 2100 may include a package substrate body 2120, package upper pads 2130 disposed on a top face of the package substrate body 2120, package lower pads 2125 disposed on a bottom face of the package substrate body 2120 or exposed through the bottom face, and inner wires 2135 disposed inside the package substrate body 2120 for electrically connecting the upper pads 2130 and the lower pads 2125 to each other. The upper pads 2130 may be electrically connected to connection structures 2400. The lower pads 2125 may be connected to the wire patterns 2005 of the main substrate 2010 of the electronic system 2000 as shown in FIG. 45 via conductive connectors 2800.

Each of the semiconductor chips 2200 may include a semiconductor substrate 3010, and a first structure 3100 and a second structure 3200 that are sequentially stacked on the semiconductor substrate 3010. The first structure 3100 may include a peripheral circuit area including peripheral wires 3110. The second structure 3200 may include a source conductive layer 3205, first and second stack structures 3210 on the source conductive layer 3205, channel structures 3220 and separation structures 3230 extending through the first and second stack structures 3210, bit lines 3240 electrically connected to the memory channel structures 3220, and gate connection wires (1115 of FIG. 44) electrically connected to the word lines (WL in FIG. 44) of the gate stack structure 3210. In the second structure 3200, as shown in the enlarged view, a channel hole CH including a first channel hole CH1 extending through the first stack structure ST1 and a second channel hole CH2 extending through the second stack structure ST2 may be formed. The first channel hole CH1 may include a first lower channel hole CH1L which extends through a lower portion of the first stack structure ST1 and thus extends through some of the first gate electrodes 145, and a first upper channel hole CH1H extending through an upper portion of the first stack structure ST1 and thus extending through the other of the first gate electrodes 145. The first upper channel hole CH1H may extend through the first interlayer insulating film 160. The second channel hole CH2 may extend through the second gate electrode 245. The first upper channel hole CH1H may be connected to the first lower channel hole CH1L, while the second channel hole CH2 may be connected to the first upper channel hole CH1H. A side wall of the first channel hole CH may have an inclination change at a boundary between the first lower channel hole CH1L and the first upper channel hole CH1H. A side wall of the first lower channel hole CH1L may have a first inclination relative to the third direction DR3. A side wall of the first upper channel hole CH1H may have a second inclination relative to the third direction DR3, wherein the second inclination may be different from the first inclination. The second inclination may be greater than the first inclination in one example. A side wall of the second channel hole CH2 may have a third inclination relative to the third direction DR3. The second inclination may be greater than the third inclination in one example. However, the present disclosure is not limited thereto.

Each of the semiconductor chips 2200 may include a through-wire 3245 that is electrically connected to the peripheral wires 3110 of the first structure 3100 and extends into the second structure 3200. The through-wire 3245 may extend through the gate stack structure 3210, and may be further disposed outside the gate stack structure 3210. Each of the semiconductor chips 2200 may further include an input/output connection wire 3265 that is electrically connected to the peripheral wires 3110 of the first structure 3100 and extends into the second structure 3200, and an input/output pad 2210 that is electrically connected to the input/output connection wire 3265.

Referring to FIG. 47, in a semiconductor package 2003A, each of the semiconductor chips 2200a may include a semiconductor substrate 4010, a first structure 4100 on the semiconductor substrate 4010, and a second structure 4200 disposed on the first structure 4100 and bonded to the first structure 4100 in a wafer bonding scheme.

The first structure 4100 may include a peripheral circuit area including a peripheral wire 4110 and first bonding structures 4150. The second structure 4200 may include a source conductive layer 4205, first and second stack structures 4210 between the source conductive layer 4205 and the first structure 4100, memory channel structures 4220 and a separation structure 4230 extending through the first and second stack structures 4210, and second bonding structures 4250 electrically and respectively connected to the word lines (WL in FIG. 1) of the gate stack structure 4210 and the memory channel structures 4220. For example, the second bonding structures 4250 are respectively electrically connected to the memory channel structures 4220 and the word lines (WL in FIG. 44) via the bit lines 4240 electrically connected to the memory channel structures 4220, and the gate connection wires (1115 in FIG. 44) electrically connected to the word lines (WL in FIG. 1). The first bonding structures 4150 of the first structure 4100 and the second bonding structures 4250 of the second structure 4200 may be bonded to each other while being in contact with each other. Bonding portions between the first bonding structures 4150 and the second bonding structures 4250 may be made of copper (Cu) in one example.

In the second structure 4200, as shown in the enlarged view, a channel hole CH including a first channel hole CH1 extending through the first stack structure ST1 and a second channel hole CH2 extending through the second stack structure ST2 may be formed. The first channel hole CH1 may include a first lower channel hole CH1L which extends through a lower portion of the first stack structure ST1 and thus extends through some of the first gate electrodes 145, and a first upper channel hole CH1H extending through an upper portion of the first stack structure ST1 and thus extending through the other of the first gate electrodes 145. The first upper channel hole CH1H may extend through the first interlayer insulating film 160. The second channel hole CH2 may extend through the second gate electrode 245. The first upper channel hole CH1H may be connected to the first lower channel hole CH1L, while the second channel hole CH2 may be connected to the first upper channel hole CH1H. A side wall of the first channel hole CH may have an inclination change at a boundary between the first lower channel hole CH1L and the first upper channel hole CH1H. The side wall of the first lower channel hole CH1L may have a first inclination relative to the third direction DR3. The side wall of the first upper channel hole CH1H may have a second inclination relative to the third direction DR3, wherein the second inclination may be different from the first inclination. The second inclination may be greater than first inclination in one example. The side wall of the second channel hole CH2 may have a third inclination relative to the third direction DR3. The second inclination may be greater than the third inclination in one example. However, the present disclosure is not limited thereto. Each of the semiconductor chips 2200a may further include an input/output pad 2210 and an input/output connection wire 4265 under the input/output pad 2210. The input/output connection wire 4265 may be electrically connected to some of the second bonding structures 4250.

The semiconductor chips 2200 in FIG. 46 and the semiconductor chips 2200a in FIG. 47 may be electrically connected to each other via bonding wire-type connection structures 2400. However, in example embodiments, semiconductor chips in a single semiconductor package such as the semiconductor chips 2200 in FIG. 46 and the semiconductor chips 2200a in FIG. 47 may be electrically connected to each other via a connection structure including a through-electrode TSV.

Although the embodiments of the present disclosure have been described with reference to the accompanying drawings, the present disclosure is not limited to the embodiments, but may be modified in various different forms. Those of ordinary skill in the technical field to which the present disclosure belongs will be able to understand that the present disclosure may be implemented in other specific forms without changing the technical idea or essential characteristics of the present disclosure. Therefore, the embodiments as described above are example in all respects and should be understood as non-limiting.

What is claimed is:

1. A semiconductor device comprising:
a substrate;
a first stack structure on the substrate, wherein the first stack structure comprises a plurality of first gate electrodes stacked in a first direction;
a second stack structure on the first stack structure, wherein the second stack structure comprises a plurality of second gate electrodes stacked in the first direction;
a channel hole comprising:
a first lower channel hole that extends through a lower portion of the first stack structure;
a first upper channel hole connected to the first lower channel hole, wherein the first upper channel hole extends through an upper portion of the first stack structure; and
a second channel hole connected to the first upper channel hole, wherein the second channel hole extends through the second stack structure; and
a channel structure in the channel hole,
wherein a side wall of the first lower channel hole has a first inclination relative to the first direction,
wherein a side wall of the first upper channel hole has a second inclination relative to the first direction, wherein the second inclination is different from the first inclination, and
wherein a side wall of the second channel hole has a third inclination relative to the first direction, wherein the third inclination is different from the second inclination.

2. The semiconductor device of claim 1, wherein the second inclination has a higher degree of inclination from the first direction than the first inclination.

3. The semiconductor device of claim 1, wherein a second direction intersects the first direction, and
wherein a width of the first lower channel hole in the second direction, a width of the first upper channel hole in the second direction, and a width of the second channel hole in the second direction each increase with increasing distance from the substrate.

4. The semiconductor device of claim 1,
wherein a second direction intersects the first direction, and
wherein at a boundary between the first upper channel hole and the second channel hole, a width of the first upper channel hole in the second direction is greater than a width of the second channel hole in the second direction.

5. The semiconductor device of claim 1,
wherein the first stack structure further comprises a first interlayer insulating film in contact with the second stack structure, and
wherein the first upper channel hole extends through the first interlayer insulating film.

6. The semiconductor device of claim 1, wherein the channel structure comprises:
a channel insulating film on a surface of the channel hole;
a channel film on the channel insulating film; and
a channel filling film in the channel hole and on the channel film.

7. The semiconductor device of claim 6, further comprising:
a source conductive layer and a support layer between the substrate and the first stack structure,
wherein the source conductive layer and the support layer are sequentially stacked in the first direction, and
wherein the support layer electrically connects the source conductive layer and the channel film to each other.

8. The semiconductor device of claim 1, further comprising:
a source conductive layer between the substrate and the first stack structure,
wherein the channel structure comprises a channel film, and a channel filling film in a space defined by the channel film,
wherein a bottom of the channel film is in direct contact with the source conductive layer.

9. A semiconductor device comprising:
a substrate;
a first stack structure on the substrate and comprising a plurality of first inter-electrode insulating films and a plurality of first gate electrodes alternately stacked in a first direction;
a second stack structure on the first stack structure, and comprising a plurality of second inter-electrode insulating films and a plurality of second gate electrodes alternately stacked in the first direction;
a channel hole comprising:
a first lower channel hole that extends through a lower portion of the first stack structure;
a first upper channel hole that is connected to the first lower channel hole and extends through an upper portion of the first stack structure; and
a second channel hole that is connected to the first upper channel hole and extends through the second stack structure;
a channel structure comprising:
a channel insulating film on a surface of the channel hole;
a channel film on the channel insulating film; and
a channel filling film on the channel film and in the channel hole;
a source conductive layer between the substrate and the first stack structure; and
a support layer between the source conductive layer and the first stack structure, wherein the support layer extends through the channel insulating film and directly contacts the channel film,
wherein a side wall of the first lower channel hole has a first inclination relative to the first direction,
wherein a side wall of the first upper channel hole has a second inclination relative to the first direction, wherein the second inclination is different from the first inclination, and
wherein a side wall of the second channel hole has a third inclination relative to the first direction, wherein the third inclination is different from the second inclination.

10. The semiconductor device of claim 9,
wherein the first upper channel hole extends through ones of the plurality of first gate electrodes, and
wherein the support layer is on a bottom surface of the channel film.

11. The semiconductor device of claim 9,
wherein a second direction intersects the first direction,
wherein a width of the first lower channel hole in the second direction, a width of the first upper channel hole in the second direction, and a width in the second direction of the second channel hole each increase with increasing distance from the substrate, and
wherein the second inclination has a higher degree of inclination from a the first direction than the first inclination and the third inclination.

12. The semiconductor device of claim 9,
wherein the first upper channel hole does not extend through the plurality of first gate electrodes, and
wherein the first upper channel hole extends through a first inter-electrode insulating film farthest from the substrate among the plurality of first inter-electrode insulating films.

13. The semiconductor device of claim 12, further comprising:
a first interlayer insulating film comprising an extension along a profile of the side wall of the first upper channel hole,
wherein the channel structure is on the first interlayer insulating film.

14. The semiconductor device of claim 13, wherein the first interlayer insulating film further comprises a protrusion that protrudes from the extension toward the channel structure.

15. The semiconductor device of claim 9,
wherein the first stack structure further comprises a first interlayer insulating film in contact with the second stack structure, and
wherein the first upper channel hole extends through the first interlayer insulating film.

16. The semiconductor device of claim 9,
wherein the first stack structure further comprises a first interlayer insulating film, and a second interlayer insulating film between the first interlayer insulating film and the second stack structure,
wherein the channel hole further comprises a first middle channel hole connected to and between the first lower channel hole and the first upper channel hole,
wherein the first middle channel hole extends through the first interlayer insulating film,
wherein the first upper channel hole extends through the second interlayer insulating film, and
wherein the first lower channel hole extends through the first interlayer insulating film.

17. The semiconductor device of claim 16,
wherein a second direction intersects the first direction, and
wherein a width of the first upper channel hole in the second direction decreases with increasing distance from the substrate.

18. The semiconductor device of claim 16,
wherein a second direction intersects the first direction, and
wherein at a boundary between the first upper channel hole and the first middle channel hole, a width of the first upper channel hole in the second direction is greater than a width of the first middle channel hole in the second direction.

19. An electronic system comprising:
a main substrate;
a semiconductor device on the main substrate; and
a controller on the main substrate and electrically connected to the semiconductor device,
wherein the semiconductor device comprises:
a first structure comprising a peripheral circuit;
a second structure comprising an input/output connection wire electrically connected to the peripheral circuit; and
an input/output pad electrically connected to the input/output connection wire that extends into the second structure,
wherein the second structure comprises:
a first stack structure on a substrate, wherein the first stack structure comprises a plurality of first gate electrodes stacked in a first direction;
a second stack structure on the first stack structure, wherein the second stack structure comprises a plurality of second gate electrodes stacked in the first direction;
a channel hole comprising:
a first lower channel hole that extends through a lower portion of the first stack structure;
a first upper channel hole connected to the first lower channel hole, wherein the first upper channel hole extends through an upper portion of the first stack structure; and
a second channel hole connected to the first upper channel hole, wherein the second channel hole extends through the second stack structure; and
a channel structure in the channel hole,
wherein a side wall of the first lower channel hole has a first inclination relative to the first direction,
wherein a side wall of the first upper channel hole has a second inclination relative to the first direction, wherein the second inclination is different from the first inclination, and
wherein a side wall of the second channel hole has a third inclination relative to the first direction, wherein the third inclination is different from the second inclination.

20. The electronic system of claim 19,
wherein the channel structure comprises:
a channel insulating film on a surface of the channel hole;
a channel film on the channel insulating film; and
a channel filling film on the channel film and in the channel hole, and
wherein the second structure further comprises:
a source conductive layer between the substrate and the first stack structure; and
a support layer between the source conductive layer and the first stack structure,
wherein the support layer extends through the channel insulating film and directly contacts the channel film.
